(19) United States
(12) Patent Application Publication
(10) Pub. No.: US 2025/0392104 A1
(43) Pub. Date: Dec. 25, 2025

(54) LOW CAPACITANCE DEVICE AND METHOD OF MANUFACTURING THE SAME

(71) Applicant: VI Systems GmbH, Berlin (DE)

(72) Inventors: Nikolay Ledentsov, Berlin (DE); Vitaly Shchukin, Berlin (DE)

(73) Assignee: VI Systems GmbH, Berlin (DE)

(21) Appl. No.: 19/198,087

(22) Filed: May 4, 2025

Related U.S. Application Data
(63) Continuation-in-part of application No. 17/724,041, filed on Apr. 19, 2022.

(51) Int. Cl. H01S 5/183; H01S 5/065; H10F 30/223; H10H 20/81

(52) U.S. Cl. CPC H01S 5/18394; H01S 5/0657; H01S 5/18311; H10F 30/223; H10H 20/81

(57) ABSTRACT

A semiconductor optoelectronic device formed of a p-doped region, an undoped active region, and an n-doped region, contains at least one conducting transformation layer subject to transformation. Possible transformations include selective oxidation or selective etching or their combination resulting in a conducting aperture confined by an electrically insulating region formed of dielectric or void. The intermediate layer between the transformation layer and the active region is undoped. The conducting aperture can provide induced doping of a part of the intermediate layer close to the aperture, enabling electric conductivity towards the active region, while the other parts of the initially undoped intermediate layer remain undoped. This results in a significant reduction of the area of the p-n junction, and, thus, in a significant reduction of the device capacitance. The disclosure applies to vertical cavity surface emitting lasers (VCSELs) and to other types of light-emitting devices as well as to photodetectors.

### REFERENCE TO RELATED APPLICATIONS

This is a continuation-in-part of U.S. patent application Ser. No. 17/724,041, filed Apr. 19, 2022, entitled: “High Speed Narrow Spectrum Miniarray of VCSELs and Data Transmission Device Based Thereupon”, US Patent Application publication No. US2022/0368113A1, published Nov. 17, 2022. The aforementioned application is hereby incorporated herein by reference.

### BACKGROUND OF THE INVENTION

### Field of the Invention

The invention pertains to the field of optoelectronic devices. More particularly, the invention pertains to light emitting devices.

### Description of Related Art

There is a need in optoelectronic devices suitable for high-speed data communication and pulse generation and detection.

In the parent patent application by Ledentsov et al., U.S. Ser. No. 17/724,041, referred hereafter as Ledentsov '041 miniarrays of vertical cavity surface emitting lasers (VCSELs) were disclosed. Such miniarrays exhibit advantage versus single aperture VCSELs from two perspectives. First, for small individual aperture sizes, preferably close to ˜4 μm, the fluctuations of a value of ˜0.5 μm shifts the wavelength less than by 0.2 nm. This enables a rather narrow emission spectrum from a miniarray of VCSELs, with sufficient emission power and with root mean square of the emission spectrum below 0.6 nm, and even below 0.1 nm. This enhances the maximum distance for the error-free data transmission over a multimode optical fiber (MMF), as the narrow spectral width of the emission spectrum reduces the negative effect of the chromatic dispersion in the MMF. Second, closely spaced apertures in a miniarray with a lateral spacing between apertures preferably below 10 μm allow coherent optical coupling between neighboring apertures and formation of coupled optical modes (supermodes). Once the spectral splitting of the supermodes, say, in two-aperture miniarray of VCSELs lasing in the 850 nm spectral range is larger than 0.1 nm (˜40 GHz), the interaction between optical modes may result in a significantly higher (−3 dB) cutoff frequency of the modulation curve with respect to VCSELs with a single aperture, which allows data transmission at a significantly higher bit rate.

However, improvement in optical properties of the optoelectronic devices is not sufficient for high-speed data communication. A one skilled in the art will recognize that there is additional factor limiting the high speed performance of optoelectronic devices. The speed of such devices containing p-n junction is often limited by electric parasitic effects. Electric parasitic is dominated by device resistance and capacitance. The product of resistance to capacitance defines the limiting parasitic bandwidth that reduces the ultimate modulation bandwidth and the maximum possible rate of data transmission as well as a minimum possible pulse width. For a given resistance of the chip the capacitance is the key factor limiting the time response of the device.

The interplay of optical and electrical limiting factors for high-speed operation of single-aperture and multi-aperture VCSELs was addressed in the non-patent publication by Ledentsov et al., “Intrinsic Modulation Response and Electrical Parasitics in Oxide-confined Vertical-Cavity Surface-Emitting Lasers Based on Single or Multiple Apertures”, Electronic Letters 2025, paper 61:e70234, https://doi.org/10.1049/ell2.70234, referred to hereafter as Ledentsov '25, wherein both factors were individually extracted from the experimental data and analysed. The publication in its entirety is hereby incorporated herein in its entirety by reference.

Further, for data transmission at a high data rate both light emitting device and photodetectors must exhibit high frequency properties. Thus, the present disclosure focuses on reducing the capacitance both in light-emitting devices and photodetectors.

Means to achieve a low capacitance proposed include but are not limited to using electrically insulating regions in the section of the device having a p-n junction, or using multiple stacked such regions. Such electrically insulating regions are formed, once one or several layers are subject to transformation. Such transformations include, e.g. selective oxidation of AlAs or Ga(1−x)Al(x)As layers with a high aluminum composition in water vapor atmosphere, resulting in the formation of an insulating amorphous oxide AlO(y) or Ga(1−x)Al(x)O(y). Such oxide can be optionally removed forming a void, and such void can be optionally filled with another dielectric material. A different approach includes selective chemical etching of one or several layers forming voids. Such voids can also be optionally filled by dielectric material. Thus, such transformation process results in the formation of electrically conducting aperture laterally confined by electrically insulating region formed by voids, dielectric or their combination. A one skilled in the art will appreciate that the oxidation of Ga(1−x)Al(x)As occurs predominantly in the layers with high aluminum composition (say, x>0.95), and chemical etching can also be made selective to occur only in the predefined layers by using selective etchants.

The size of the electrically conducting aperture can be decisive for the capacitance of the device. Previously it was shown that in case of oxide-confined VCSELs apertures with a small aperture diameter reduce the diffusion capacitance of the device by limiting laterally the surface of the region where electrons and holes are injected. This was demonstrated in the non-patent publication by Kalosha, et al., “Comprehensive Analysis of Electric Properties of Oxide-Confined Vertical-Cavity Surface-Emitting Lasers”, IEEE Journal of Selected Topics in Quantum Electronics, volume 25, issue 6, pages 1-9 (2019), whereas the publication is hereby incorporated herein in its entirety by reference. It was also shown in this publication that the depletion capacitance is mostly defined by the surface area of the p-n junction. In practical VCSELs depletion capacitance dominates.

Application of voids to reduce capacitance was proposed, even rules for the practical reduction of depletion capacitance was described in the U.S. Pat. No. 8,447,187, “OPTOELECTRONIC INTERCONNECT FOR HIGH FREQUENCY DATA TRANSMISSION AT LOW POWER CONSUMPTION”, filed Feb. 17, 2011, issued May 21, 2013, invented by the inventors of the present invention, whereas the patent is hereby incorporated herein in its entirety by reference.

A simple way to form isolated conducting apertures inside a non-conducting matrix is described in multiple publications. For example, in the In(y)Ga(1−y)P—In(y)Ga(1−y)As—Ga(1−x)Al(x)As materials system (for simplicity denoted also as InGaP—InGaAs—GaAlAs materials system) the selective etching of InGaP or InP or InGaAs can be realized by using HCl, CH₃COOH, and H₂O₂. The approach is described in non-patent publications by Flemish and Jones “Selective Wet Etching of GaInP, GaAs, and InP in Solutions of HCl, CH₃COOH, and H₂O₂,” Journal of Electrochemical Society, volume 140, issue 3, pp. 844-847, March 1993; or by Ravi et al., “Effect of sulfur passivation and polyimide capping on InGaAs—InP PIN photodetectors”, in IEEE Transactions on Electron Devices, volume 50, issue 2, pp. 532-534, February 2003, whereas these publications are hereby incorporated herein in their entirety by reference. A one skilled in the art will recognize that the process of layer transformation and the formation of conducting apertures laterally confined by electrically insulating environment is not limited to those chemicals.

Another process includes selective oxidation in the water vapor of the layers of AlAs or Ga(1−x)Al(x)As with a high aluminum content, which is widely applied to form oxide-confined apertures in VCSELs. The approach is described, e.g., in the non-patent application by Choquette et al., “Advances in Selective Wet Oxidation of AlGaAs Alloys,” IEEE Journal of Selected Topics in Quantum Electronics, volume 3, issue 3, pp. 916-926, June 1997, whereas the publication is hereby incorporated herein in its entirety by reference. However, in the approach where the oxide-confined aperture is not electrically isolated from the active region (i-region in PIN photodetectors, gain region in lasers or light emitting diodes), and there exists a doped region between the oxidized aperture and the active region, the residual depletion capacitance of the p-n junction in the remote sections away from the aperture, where no effective injection occurs, will remain. Furthermore, the depletion capacitance caused by the charges generated at the interface between the doped material and the oxide aperture surface having a high concentration of interface states will add an additional depletion capacitance.

Thus, there exists a need for a further reduction of device capacitance.

### SUMMARY OF THE INVENTION

Ultimate reduction of capacitance can be achieved by forming conducting apertures laterally confined by dielectric or void regions, wherein the apertures are electrically isolated from the active region (bulk double heterostructures, quantum wells, quantum wires, quantum dots, or a combination thereof) by undoped spacers. The conducting apertures are capable to induce mobile carriers to undoped spacers, thus rendering the spacers locally conducting. Upon induced doping the spacer contains an induced doped electrically conducting section close to the conducting aperture, and this electrically conducting section is laterally confined by an undoped and electrically insulating part of the spacer. The area of the p-n junction is thus significantly reduced, and the depletion capacitance of the device is reduced accordingly. The disclosed approach allows realizing both high conductivity and a low resistance of the device and ultimately low depletion capacitance.

Voids applied to confine laterally aperture regions are the one preferred solution for the reduction of capacitance. For the same thickness of the layer a void provides an ultimately low dielectric constant and, under the same other conditions, an ultimately low capacitance.

Formation of stacked regions with void- or dielectric-confined electrically isolated apertures can allow closely positioned electrically isolated columns in case of lateral arraysof vertical cavity surface-emitting lasers (VCSELs). Applying an isolated aperture region can enable the formation of under-pad matching electric circuits to minimize back reflections of high-frequency signal enabling novel types of integrated electro-optical devices.

Furthermore, recently novel approaches like self-injection locking of optical modes in coupled apertures can result in high frequency modulation of an optical signal originating at each of the coupled apertures. In an alternative regime, self-injection mode locking can be realized resulting in the operation of a device, e.g., multi-aperture VCSEL, in a single super-mode. Once the approach to self-injection locking and the approach for ultimate reduction of the device capacitance are combined in a single device, this enables a drastic increase in the broadened modulation bandwidth extended towards and beyond 100 GHz.

Further requirement reads that all these advantages can only be realized if the capacitance of the device is small enough to enable matching an effective electric circuit to cope with input electric signal on a level of 30-100 GHz and beyond.

### BRIEF DESCRIPTION OF THE DRAWINGS

FIGS. 1A through 1D. Schematic representation of a prior art device with a p-n junction.

FIG. 1A. PIN photodetector, vertical cross-section.

FIG. 1B. PIN photodetector, top view.

FIG. 1C. Light-emitting diode (LED) or a laser, vertical cross-section.

FIG. 1D. Light-emitting diode or a laser, top view. PIN operates under reverse bias. LED operates under forward bias. LED contains a dielectric-confined aperture, with a dielectric region formed, for example, by water vapor oxidation of Al(Ga)As layers.

FIGS. 2A through 2F. Schematic representation of a device according to embodiments of the present invention.

FIG. 2A and FIG. 2B. Device with a dielectric region around the aperture having no conducting layer beneath the dielectric section.

FIG. 2A: vertical cross-section.

FIG. 2B: top view.

FIG. 2C and FIG. 2D. Device with selectively etched-off region around the aperture introduced at the boundary of the p-doped and undoped regions having no conducting layer beneath the etched-off section.

FIG. 2C: vertical cross section.

FIG. 2D: top view.

FIG. 2E and FIG. 2F. Device with selectively etched-off region around the aperture introduced at the boundary of the n-doped and undoped regions having no conducting layer above the etched-off section.

FIG. 2E: vertical cross-section.

FIG. 2F: top view.

FIGS. 3A through 3E. Schematic representation of stages of fabrication of a device according to an embodiment of the present invention.

FIG. 3A. Holes are etched through the p-doped and undoped region of the device (for example, InGaAs) down to the bottom n-layer (for example, InP) underneath i-region,

FIG. 3B. Selective etchant is applied to remove selectively the layer underneath the i-region (InP). In such design the electric field under reverse bias is applied to the region between the aperture and the upper contact ring.

FIG. 3C. Further the holes are filled with a dielectric providing mechanical stability to the device.

FIG. 3D. Unnecessary sections of the device are etched off.

FIG. 4A and FIG. 4B. Possible implementations of the device design including the contact pad region.

FIG. 4A. Dielectric pattern allows realization of an RLC circuit over the doped substrate or buffer layer and under the pad allowing matching of the p-n junction device to high frequency electric circuit.

FIG. 4B. Dielectric pattern is formed on top of the semiconductor structure fully electrically isolated from the p-n junction device allowing ultimately low pad capacitance.

FIGS. 5A through 5D. Schematic illustration of a possible device processing route while illustrated from top.

FIG. 5A. Etching of holes, formation of p-contact.

FIG. 5B. Selective etching of voids.

FIG. 5C. Filling the holes with dielectric.

FIG. 5D. Removal of excessive material.

FIG. 6. Vertical cross section of the device presented in FIG. 5D.

FIGS. 7A and 7B. Illustration of the device geometry including top dielectric layers and placement of the contact pads.

FIG. 7A. Top view.

FIG. 7B. Cross-section.

FIGS. 8A through 8F. Illustration of the impact of induced doping on the band diagram with abrupt (8A, 8B, 8C) and graded (8D, 8E, 8F) interfaces:

FIGS. 8A and 8B. Valence band diagram for the valence band of undoped multilayer heterostructure on an example of AlAs—GaAs materials.

FIG. 8A. Diagram for abrupt interfaces.

FIG. 8B. Diagram for graded interfaces.

FIGS. 8C and 8D. Valence band diagram for the valence band of modulation doped multilayer heterostructure on an example of AlAs—GaAs materials, whereas only AlAs layers are p-doped with acceptor impurity, and GaAs is undoped.

FIG. 8C. Diagram for abrupt interfaces showing induced doping of initially undoped material.

FIG. 8D. Diagram for graded interfaces showing induced doping of initially undoped material.

FIGS. 8E and 8F. Valence band diagram for the valence band of modulation doped multilayer heterostructure on an example of AlAs—GaAs materials, wherein AlAs layers are selectively transformed to AlO(y).

FIG. 8E. Diagram for abrupt interfaces.

FIG. 8F. Diagram for graded interfaces.

FIGS. 9A through 9C.

FIG. 9A. Device with a single isolated aperture laterally confined by dielectric or void.

FIG. 9B. Device with multiple isolated apertures.

FIG. 9C. Device with multiple isolated apertures, wherein a conducting column surrounded by electrically insulating regions is formed and the capacitance of this section is strongly reduced.

FIG. 10A. Single conducting column device with multiple isolated apertures laterally confined by dielectric or voids.

FIG. 10B. Single conducting column device with multiple isolated dielectric or void apertures showing a possible arrangement of the contact pad directly on semiconductor without generation of significant capacitance.

FIGS. 11A through 11D. Different lateral arrangements of the device structures with multi-aperture arrays.

FIG. 11A. Schematic cross-section in the lateral plane of a multi-aperture device. Solid circles stand for holes. Dashed circles represent overlapping regions with etched or oxidized semiconductor material.

FIG. 11B. Schematic top view of a multi-aperture device. Black circles show holes used for etching and afterwards filled with a dielectric material. Diamond-shaped curves correspond to non-overlapping apertures.

FIG. 11C. Schematic cross-section in the lateral plane of a multi-aperture device with overlapping dielectric or void regions and non-overlapping apertures.

FIG. 11D. Schematic cross-section in the lateral plane of a multi-aperture device with non-overlapping dielectric or void regions and overlapping apertures.

FIGS. 12A through 12D. Further lateral arrangements suitable for generation of periodic and aperiodic arrays of the apertures.

FIG. 12A. Lateral arrangement of apertures in a multi-aperture device according to an embodiment of the present invention.

FIG. 12B. Lateral arrangement of apertures in a multi-aperture device according to another embodiment of the present invention.

FIG. 12C. Lateral arrangement of apertures in a multi-aperture device according to yet another embodiment of the present invention.

FIG. 12D. Lateral arrangement of apertures in a multi-aperture device according to a further embodiment of the present invention.

FIGS. 13A through 13C. Possible arrangements of holes to generate necessary patterns of electrically isolated apertures having a coupled optical field.

FIG. 13A. An arrangement of holes generating electrically isolated apertures having a coupled optical field, according to an embodiment of the present invention.

FIG. 13B. An arrangement of holes generating electrically isolated apertures having a coupled optical field, according to another embodiment of the present invention.

FIG. 13C. An arrangement of holes generating electrically isolated apertures having a coupled optical field, according to yet another embodiment of the present invention.

FIGS. 14A through 14E. Possible arrangements of electrically isolated apertures where one or several apertures are capped by dielectric or metal caps.

FIG. 14A. An arrangement of electrically isolated apertures, wherein one aperture is capped by a highly reflecting dielectric coating, according to an embodiment of the present invention.

FIG. 14B. An arrangement of electrically isolated apertures, wherein three apertures are capped by an anti-reflective dielectric coating, according to another embodiment of the present invention.

FIG. 14C. An arrangement of electrically isolated apertures, wherein one aperture is capped by a highly reflecting dielectric coating, and three other apertures are capped by an anti-reflective dielectric coating, according to yet another embodiment of the present invention.

FIG. 14D. An arrangement of electrically isolated apertures of alternating small and large lateral size, according to a further embodiment of the present invention.

FIG. 14E. An arrangement of electrically isolated apertures of alternating small and large lateral size, wherein one aperture is capped by a highly reflecting dielectric coating, according to an additional embodiment of the present invention.

FIGS. 15A through 15D. Possible shapes of apertures where the apertures are optically coupled and suitable for phase injection locking aimed at the broadening of the modulation bandwidth.

FIG. 15A. Optically coupled apertures suitable for self-injection locking, according to an embodiment of the present invention.

FIG. 15B. Optically coupled apertures suitable for self-injection locking, according to another embodiment of the present invention.

FIG. 15C. Optically coupled apertures suitable for self-injection locking, according to yet another embodiment of the present invention.

FIG. 15D. Optically coupled apertures suitable for self-injection locking, according to a further embodiment of the present invention.

FIGS. 16A and 16B. Cross section in the vertical plane of the device with several apertures wherein each aperture is contacted by individual electric contact.

FIG. 16A. Cross section in the vertical plane of the device with several apertures wherein each aperture is contacted by individual electric contact, according to an embodiment of the present invention.

FIG. 16B. Cross section in the vertical plane of the device with several apertures wherein each aperture is contacted by individual electric contact, according to another embodiment of the present invention.

FIGS. 17A and 17B. Cross section in the vertical plane of the device with apertures stacked in the vertical direction.

FIG. 17A. A device with several stacked apertures having similar shape and size, according to an embodiment of the present invention.

FIG. 17B. A device with several stacked apertures having different shapes and/or sizes according to another embodiment of the present invention.

FIGS. 18A through 18D. Cross-section in the vertical plane of vertical cavity surface-emitting lasers (VCSELs), according to various embodiments of the present invention, containing an undoped layer sandwiched between an oxide-confined aperture and an active region.

FIG. 18A. A VCSEL with two doped DBRs.

FIG. 18B. A VCSEL with top intracavity contact.

FIG. 18C. A VCSEL with two intracavity contacts.

FIG. 18D. A VCSEL with two dielectric DBRs.

FIGS. 19A through 19G. Schematic representation of stages of fabrication of the device on semi-insulating substrate according to an embodiment of the present invention.

FIG. 19A. Holes are etched through the p-doped and undoped region of a device (for example, InGaAs) down to the bottom n-layer (for example, InP) underneath i-region,

FIG. 19B. Selective etchant is applied to remove selectively the layer under the i-region (InP). In such design the electric field under reverse bias is applied to the region between the aperture and the upper contact ring.

FIG. 19C. Further the holes are filled with a dielectric providing mechanical stability to the device.

FIG. 19D. Unnecessary sections of the device are etched off forming a first mesa.

FIG. 19E. Bottom n-contact is mounted on the n-doped etch-stop (for example, InGaAs layer).

FIG. 19F. Part of the etch-stop layer is etched off down to the semi-insulating substrate forming a second mesa.

FIG. 19G. A device fabricated on a semi-insulating InP substrate, according to another embodiment of the present invention.

FIG. 20A. Schematic profile of the electric field strength of the even and odd optical modes in a two-aperture miniarray of VCSELs.

FIG. 20B. Optically coupled apertures of a two-aperture miniarray of VCSELs suitable for self-injection locking, same as in FIG. 15B.

FIG. 20C. Schematic profile of the electric field strength of the even and odd optical modes in two-aperture miniarray of VCSELs.

FIG. 20D. Schematic representation of a two-aperture mini array of VCSELs, wherein highly reflecting (HR) coating is deposited on the central parts of each of two apertures, and anti-reflective (AR) coating is deposited on an intermediate area between two apertures, aimed to provide a single mode lasing in the self-injection locking regime.

FIG. 21A. Schematic representation of a two-aperture miniarray of VCSELs, wherein two coupled apertures form a bow-tie aperture, according to yet another embodiment of the present invention.

FIG. 21B. Schematic representation of a two-aperture mini array of VCSELs, two coupled apertures form a bow-tie aperture, highly reflecting (HR) coating is deposited on the central parts of each of two apertures, and anti-reflective (AR) coating is deposited on an intermediate area (bridge) between two apertures, aimed to provide a single mode lasing in the self-injection locking regime, according to a further embodiment of the present invention.

FIG. 21C. Schematic representation of a two-aperture mini array of VCSELs, two coupled apertures form a bow-tie aperture, highly reflecting (HR) coating is deposited on the central parts of each of two apertures, and anti-reflective (AR) coating is deposited everywhere else on the surface, according to another embodiment of the present invention.

FIGS. 22A through 22E. Schematic representation of longwavelength wafer-fused VCSEL, according to another embodiment of the present invention.

FIG. 22A. Schematic band diagram of p+/n+ homojunction illustrating the functional principle of the tunnel junction.

FIG. 22B. Schematic cross-section in a vertical plane of a wafer-fused tunnel-junction-based prior art VCSEL.

FIGS. 22C through 22E. Schematic representation of the fabrication process of a wafer-fused tunnel-junction-based VCSEL, according to an embodiment of the present invention.

FIG. 22C. Processed VCSEL chip wherein p+- and n+ InGaAs layers are exposed to the air at the mesa edge.

FIG. 22D. Processed VCSEL chip wherein p+- and n+ InGaAs are selectively etched, forming a tunnel junction aperture.

FIG. 22E. Processed VCSEL chip, wherein the selectively etched region is filled by a dielectric, thus forming a VCSEL with a tunnel-junction aperture, with a reduced area of the tunnel junction compared to the mesa area, thus the device capacitance being reduced.

FIGS. 23A through 23F describe a process of the fabrication of a wafer-fused tunnel-junction-based VCSEL, according to another embodiment of the present invention.

FIG. 23A shows schematically a vertical cross-section of an InP-based wafer containing an active region and terminated by a sequence of 2 layers of InGaAs, p+- and n+.

FIG. 23B shows schematically a result of selective etching of two top layers, forming sandwiched p+- and n+-doped InGaAs layer.

FIG. 23C shows a structure overgrown by an undoped InP.

FIG. 23D shows a structure, in which undoped InP layer is selectively etched off to open buried n+-doped InGaAs layer.

FIG. 23E shows a structure, in which n-doped InP is grown forming an electric contact to the open n+-doped InGaAs layer.

FIG. 23F shows schematically a wafer-fused VCSEL, in which the tunnel-junction aperture is confined in the lateral plane by an undoped material, thus reducing the capacitance of the device.

### DETAILED DESCRIPTION OF THE INVENTION

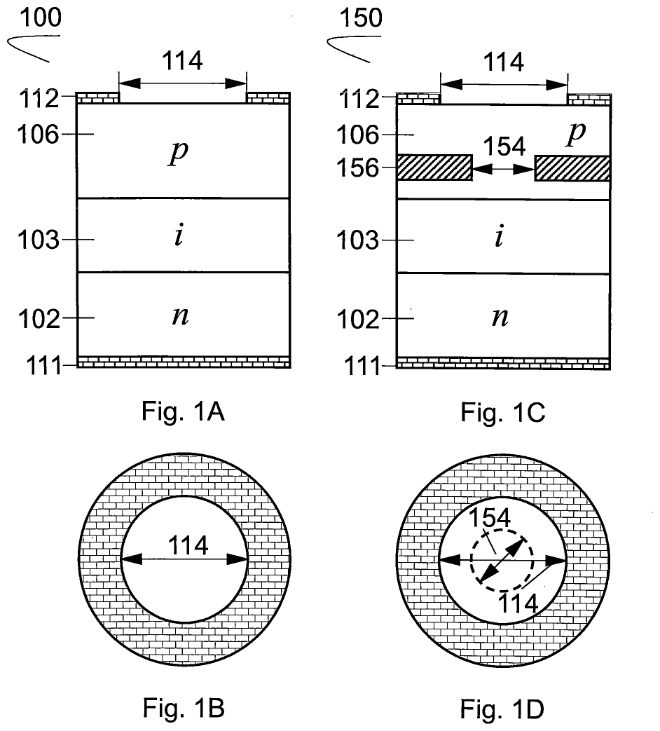

Schematic views of prior art devices are shown in FIGS. 1A through 1D. Devices (100) or (150) are fabricated in mesa geometry etched from multilayer epitaxial wafer including a p-doped region (106), an n-doped region (102) and an absorption region (i-region) (103). These regions represent, generally, multilayer sequences.

A one skilled in the art will recognize that the photodetector contains an absorption region, where the incoming light is absorbed generating electron-hole pairs, and, once the device operates under the reverse bias of the p-n junction, the electric field in the absorption region leads to the drift of electrons to the n-region, and to the drift of the holes to the p-region thus resulting in electric current in the electric circuit. On the contrary, light-emitting devices contain a gain region further containing a gain medium, where once the device operates under the forward bias of the p-n junction, electrons and holes are injected into the gain medium generating optical gain. In many aspects of the present invention, where the reduction of the device capacitance is targeted, approaches to photodetectors and to light-emitting devices show a certain similarity. Therefore, for the convenience, both the absorption region in photodetectors and gain region in light-emitting devices will be referred hereafter as “active region”.

The structure (100) in FIGS. 1A and 1B is typical for p-i-n (PIN) photodetectors. In the case of the design presented in FIG. 1A the light is directed from the top aperture (114), which is covered by an anti-reflective coating and a reverse bias is applied to generate electric field. Light entering the aperture region is absorbed and non-equilibrium electrons and holes are generated are separated to the p-contact (112) and the n-contact (111). The frequency response of the device is controlled by the electric field and the thickness of the active region, wherein both determine the time-of-flight of non-equilibrium carriers and is also controlled by electric parasitics mostly determined by p-n-junction capacitance and by series resistance. In general, the resistance is also fixed by an input resistance of the amplifier, which is often as high as 50Ω. For many applications in short distance communication the size of the aperture has to exceed 20 μm to enable coupling from a multimode fiber. This results in a high depletion capacitance and the time response is poor even though the time-of-flight is short.

In FIGS. 1C and 1D a light emitting device (150) is presented. In this case the device operates under forward bias and nonequilibrium carriers are injected into the active region. In many cases, like vertical-cavity surface-emitting lasers (VCSELs), oxide-confined apertures are applied. One or several layers are formed, e.g., of pure AlAs or of Ga(1−x)Al(x)As alloy with a high Al composition (preferably >95%), and subject to selective oxidation in water vapor. As a result of the partial oxidation of such layer, the amorphous (Ga)AlO(y) oxide is formed (156), and only a part of the layer (154) forms an electrically conducting aperture. The oxide layers may generate defects once subjected to significant concentrations of non-equilibrium carriers. The non-equilibrium carriers that reach the oxide layers recombine there non-radiatively. Energy released in the process of non-radiative recombination can be sufficient to break certain chemical bonds and to create structural defects. Such defects can grow towards the active region. Thus, additional intermediate doped layers are introduced to ensure device reliability. For example, p-doped layers are placed in between the aperture and the active region which was disclosed in the US patent “RELIABLE HIGH-SPEED OXIDE-CONFINED VERTICAL-CAVITY SURFACE-EMITTING LASER”, U.S. Pat. No. 10,516,251, filed Jun. 23, 2017, issued Dec. 24, 2019, invented by the inventors of the present invention, wherein the patent is hereby incorporated herein in its entirety by reference.

Under forward bias the main source of capacitance of the device in the active region is diffusion capacitance related to the injected nonequilibrium carriers. Depletion capacitance is strongly reduced upon forward bias only in the aperture region. The voltage applied to the passive sections beneath the oxide layers (156) is lower and the residual depletion capacitance is higher in these regions. Furthermore, the interface between the oxide layer (156) aperture and p-doped layer (106) is charged due to a high concentration of surface states providing an additional mechanism for depletion capacitance.

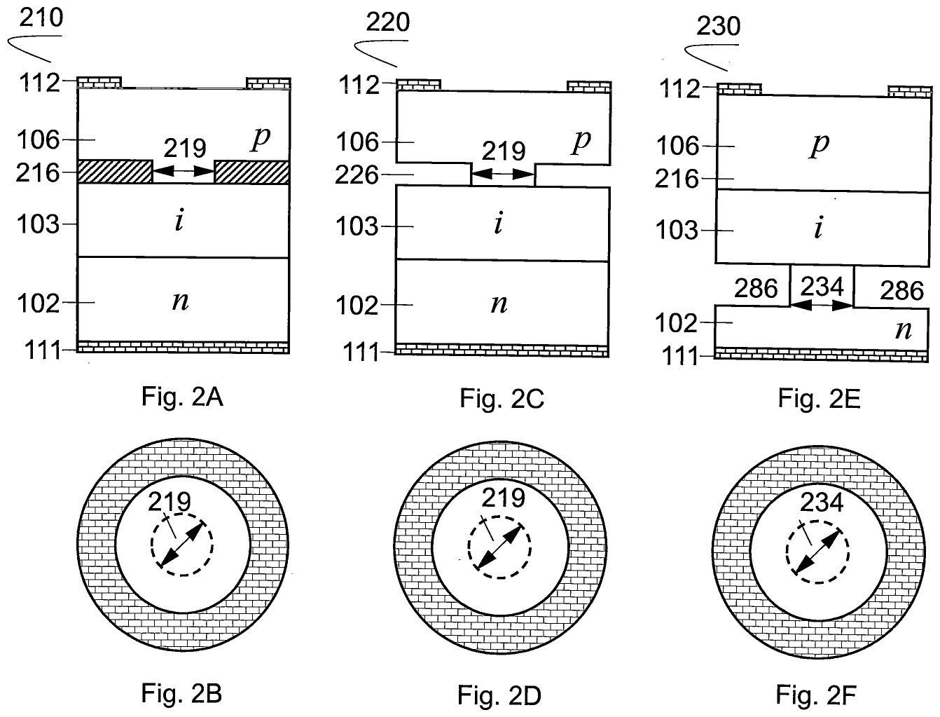

An alternative approach to an optoelectronic device is presented in FIGS. 2A through 2F. The role of depletion capacitance is strongly suppressed in case there is no doped layer between the aperture and the active region. The device (210) contains an oxide layer (216) confining the aperture (219), the layers being located directly on top of the undoped active region (103). The cross-section of the device is depicted in FIG. 2A, whereas FIG. 2B represents the top view.

FIGS. 2C and 2D show the cross-section and the top view of the device (220), wherein the oxide in the oxidized layer is removed forming a void (226).

FIGS. 2E and 2F depict the cross-section and the top view of the device (230), wherein a layer on top of the n-doped region (102), the layer being adjacent to the undoped active region (103) is selectively oxidized, and oxide is removed forming a void (286) confining the aperture (234) in the n-doped region.

However, in this approach, demonstrated by the devices in FIGS. 2A through 2F lack of intermediate layers between the aperture and the active region may result in fast degradation of light emitting devices. Furthermore, applying selectively etched voids adds fragility to the crystalline structure and stimulates the formation of defects.

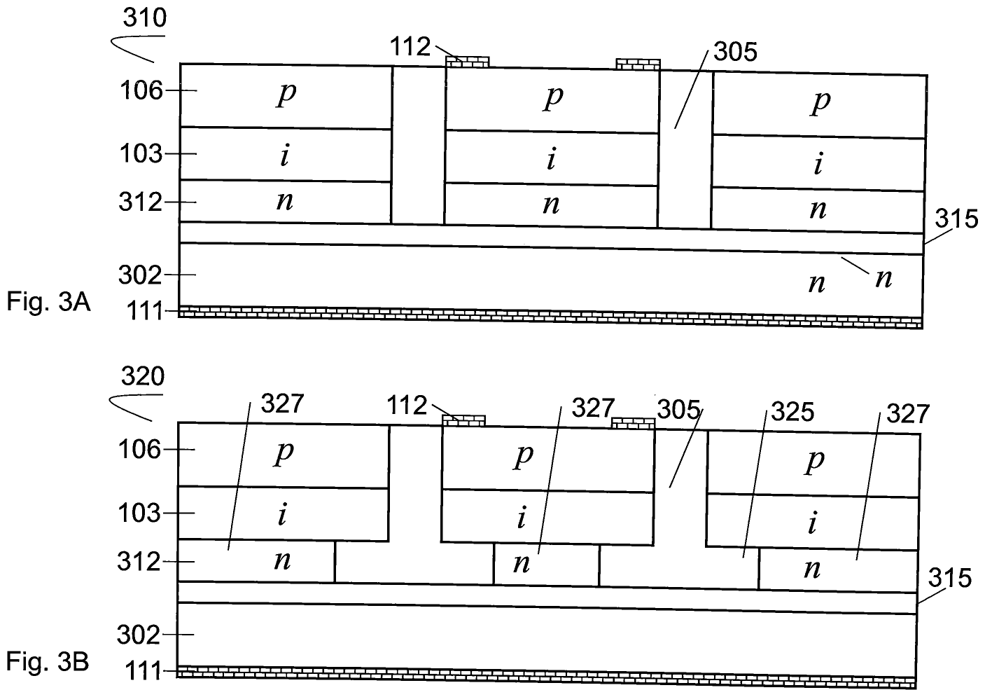

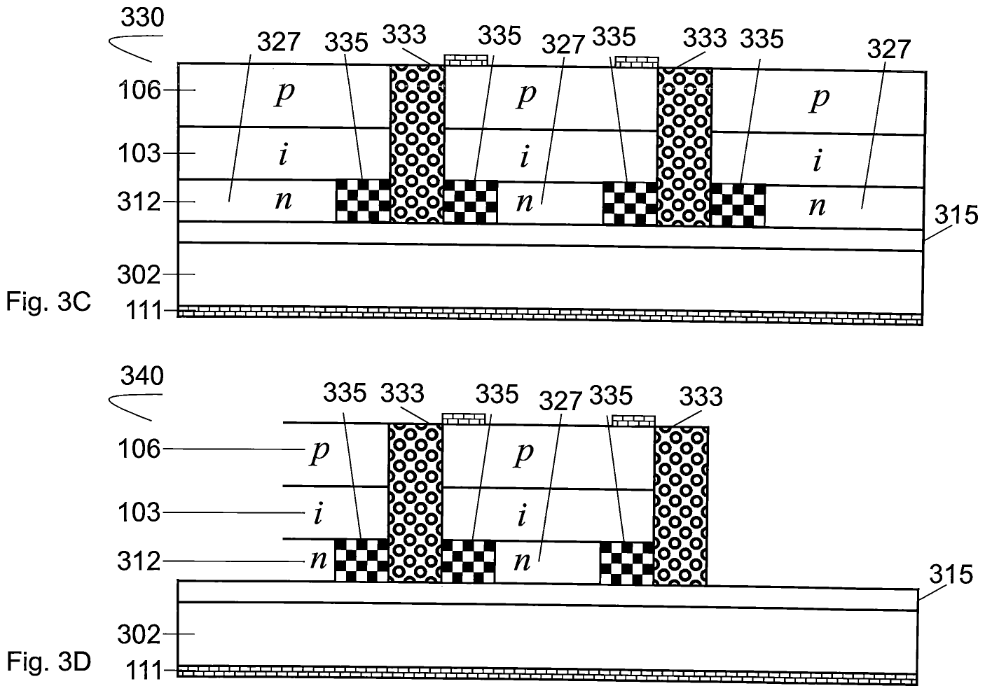

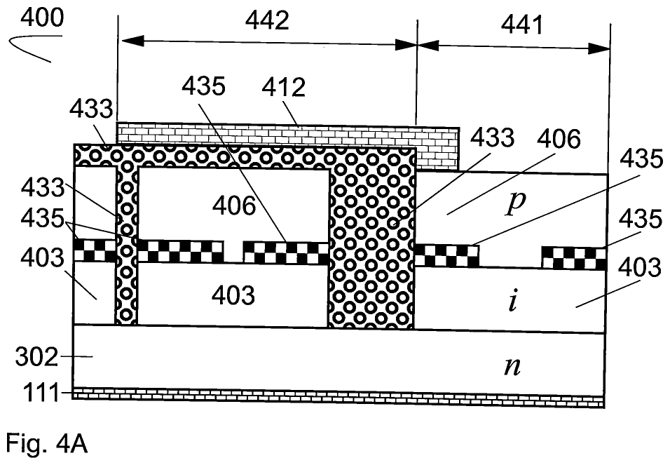

The present invention discloses an approach to prevent the fragility of the device. The approach is illustrated in FIGS. 3A through 3D on an example of a PIN structure. FIG. 3A illustrates a structure (310), wherein the n-doped section consists of a bottom n-doped part (302), an etch-stop layer (315), and a top n-doped part (312). For example, for a device containing the top p-region (106) and the undoped i-region (103) formed of InGaAs and the top part (312) of the n-doped region, the non-selective dry etching can be applied for the etching of holes (305) through the top p-doped region (106) and undoped i-region (103). Then the process can be followed by the selective wet etching of the InP layer (312) down to the etch-stop InGaAs layer (315).

FIG. 3B illustrates a further step (320) of the process where the wet etching of the layer (312) continues in the lateral directions forming the voids (325) adjacent to the vertical holes (305). It should be noted that the formation of voids, however, reduces the mechanical stability of the semiconductor structure, making it not suitable for conventional processing. The etched mushroom-like structure is fragile and can easily generate defects and dislocations not acceptable for the active section of the device.

FIG. 3B highlights a transformation of initially continuous n-doped layer (312) resulting in the formation of non-transformed parts (327) confined by voids (325). Such transformation can be driven by selective etching of parts of the InP layer (312) by a selective etchant. As a result of the transformation conducting aperture regions (327) are formed laterally confined by voids (325).

An approach disclosed in the present invention suggests a solution providing a robust manufacturing process for such an ultimately low capacitance device excluding or minimizing formation of defects. It is illustrated by FIGS. 3C and 3D and is applied as well in further embodiments.

FIG. 3C illustrates a yet further step (330) of the process where the holes (305) are filled by a dielectric (333), and parts of the etched layer (312) remain as voids (335).

FIG. 3D illustrates a further step (340) of the process where unnecessary parts of the structure are removed.

The etching of holes is important to keep the integrity of the structure and to avoid stress and dislocations. Filling the holes by a dielectric provides additional mechanical stability of the device.

A one skilled in the art will appreciate that there exist multiple ways to drive transformation of a doped layer to form conducting aperture regions (like (327)) laterally confined by electrically insulating regions (like voids (325)).

In another embodiment of the present invention the voids are also filled by a dielectric like (333).

In yet another embodiment of the present invention, a layer of AlAs or a layer of Ga(1−x)Al(x)As with a high aluminum content, preferably x>0.95, can be subject to selective oxidation in water vapor resulting in the formation of an amorphous oxide layer AlO(y) or Ga(1−x)Al(x)O(y).

In a further embodiment of the present invention, the oxide layer can be further etches off resulting in voids.

Other embodiments of the present invention include various combinations of selective etching and/or selective oxidation, and/or filling of voids.

In all these cases a transformation of a doped conducting layer occurs resulting in the formation of conducting aperture regions (or, simply, conducting apertures) laterally confined by electrically insulating regions. The surface area of the remaining conducting apertures is smaller than the surface area of the initial layer subject to transformation.

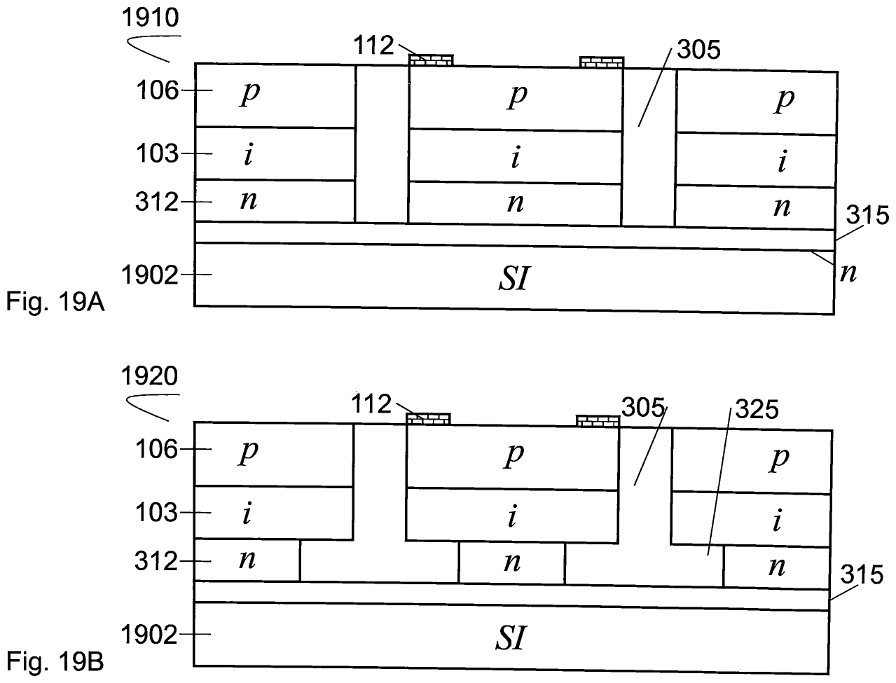

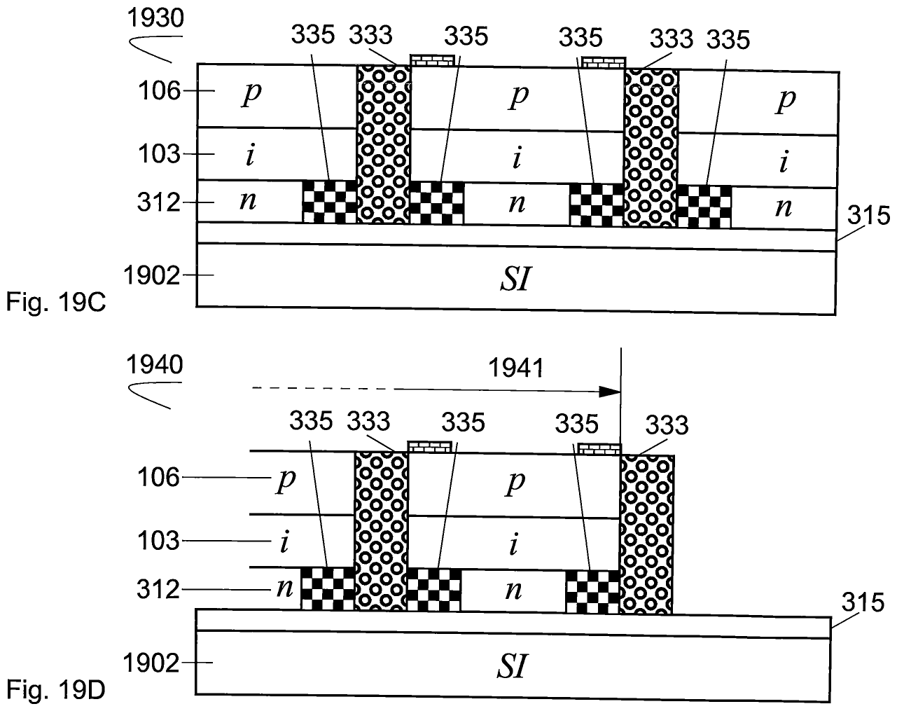

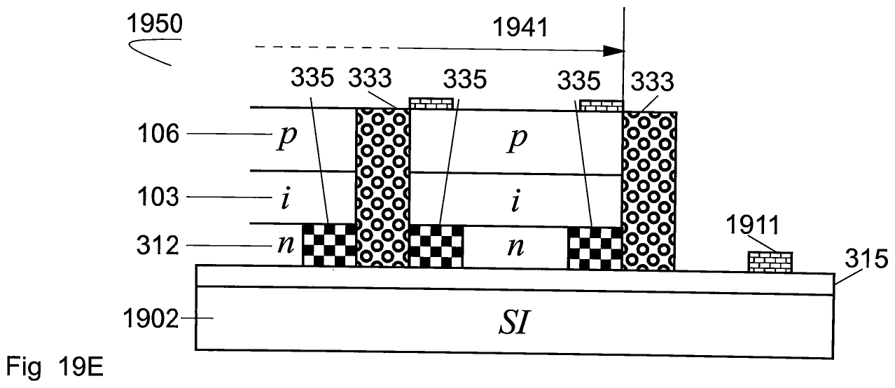

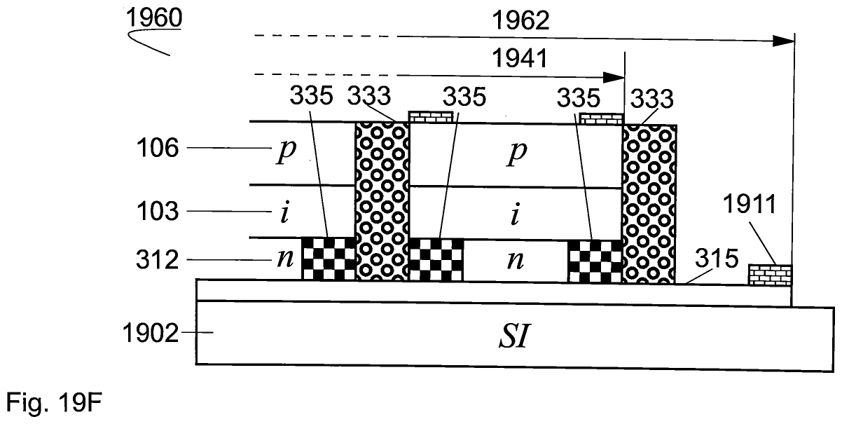

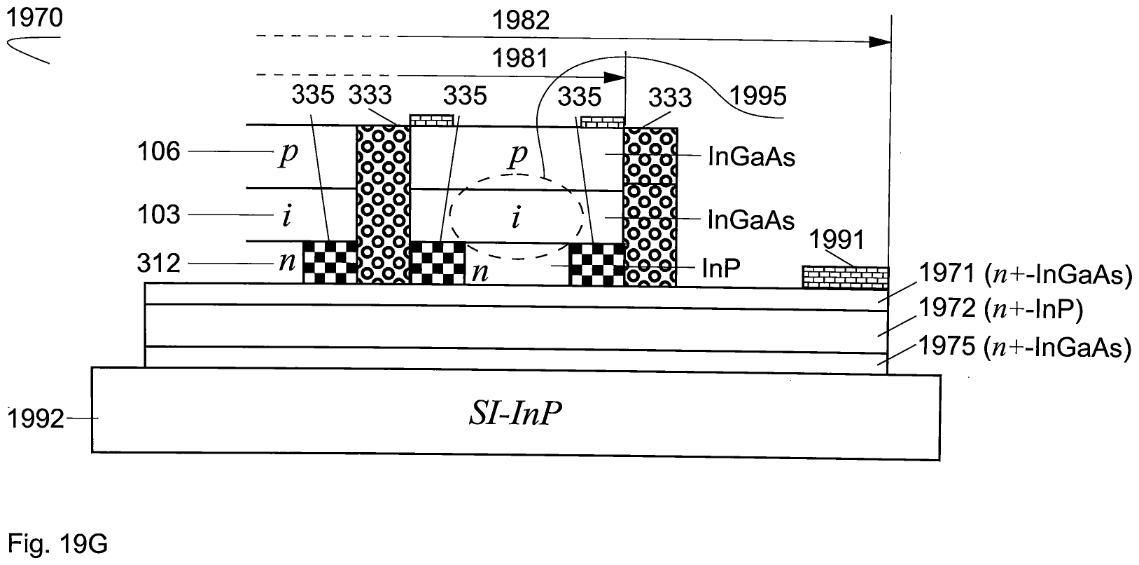

FIGS. 19A through 19G illustrate the same approach as in FIGS. 3A through 3D but applied for the fabrication of a device on a semi-insulating substrate (1902), according to another embodiment of the present invention. FIG. 19A shows the stage (1910), whereas the holes (305) are etched down to the etch-stop layer (315).

FIG. 19B shows the next stage (1920), wherein the etching of the n-doped layer (312) proceeds in the lateral plane forming extended voids (325) beneath the undoped i-layer (103).

FIG. 19C refers to the next stage (1930), wherein the holes (305) are filled by a dielectric (333), and unfilled voids (335) remain under the undoped i-layer (103).

FIG. 19D shows the next stage (1940), wherein unnecessary parts of the structure are etched off. The first mesa (1941) is formed, and the etch-stop layer (310) is partially exposed to the air.

FIG. 19E shows the next stage (1950), wherein an n-contact (1911) is mounted on the etch-stop layer (315).

FIG. 19F refers to the next stage of the process (1960), wherein a part of the etch-stop layer (315) is etched off forming the second mesa (1962).

A one skilled in the art will appreciate that, once the selective etching is employed in the process, different layers play a role of the etch-stopped layers. If an etchant is applied, that etches InP but does not etch InGaAs, then a layer InGaAs can play a role of the etch-stop layer. If an etchant is applied that etches InGaAs, but does not etch InP, then an InP layer plays a role of an etch-stop layer.

FIG. 19G illustrates schematically a device (1970), according to yet another embodiment of the present invention, the device being grown on a semi-insulating InP substrate.

The epitaxial structure of the device in FIG. 19G contains a sequence: semi-insulating InP substrate (1992), n+-doped InGaAs layer (1975), n+-doped InP layer (1972), n+-doped InGaAs layer (1971), n-doped InP layer (312), undoped i-layer (103), p-doped layer (106). The processes described above in FIGS. 19A through 19D, once applied to the structure of FIG. 19G, lead to the etching down till the first etch-stop InGaAs layer (1971) and to the formation of the first mesa (1981). At the next stage (similar to the stage of FIG. 19E), an n-contact (1991) is mounted on the first etch-stop layer (1971). Then the next stage includes etching of the layers of InGaAs (1971), InP (1972) and InGaAs (1975) by alternating etchants. The etching of the second InGaAs etch-stop layer (1975) results in the exposure of the semi-insulating InP substrate (1992) to the air and formation of the second mesa (1982). In the device (1970), the n+-doped InP layer (1972) is employed as a current spreading layer and is preferably thicker than each of the etch-stop InGaAs layers (1971) and (1975).

The residual unetched part of the n-doped (312) determines the residual area (1995) of the p-n junction and, thus, the depletion capacitance of the device. The residual unetched part of layer (312) has preferably lateral dimensions below 15 micrometers. The thickness of the n-doped layer (312) is preferably larger than 10 nanometers. Then the electric field is not uniform. The value of the electric field is lower close to the edges of the aperture. The distance between n- and p electrodes is larger than in the devices of FIGS. 1A through 2F. The electron velocity in InGaAs is higher at smaller electric fields due to a weaker transfer of carriers into the indirect valley of the conduction band in the Brillouin zone of the energy spectrum of the material. The less electrons are transferred to the indirect valley, the higher is the average drift velocity of the electrons, which compensates the longer path of the nonequilibrium carriers. The overall time-of-flight response remains about the same as for the conventional PIN structure, while the capacitance is drastically reduced due to the reduced surface (1995) of the p-n junction. A one skilled in the art will recognize that a conventional PIN photodetector with a mesa diameter of 25 μm had a typical capacitance of ˜100 femtofarad (fF). The present invention suggests a reduction of the area of the p-n junction at least by a factor of 2, thus reducing the capacitance down to ˜50 femtofarad.

A one skilled in the art will agree that the same approach applies to avalanche photodetectors, whose capacitance can also be significantly reduced.

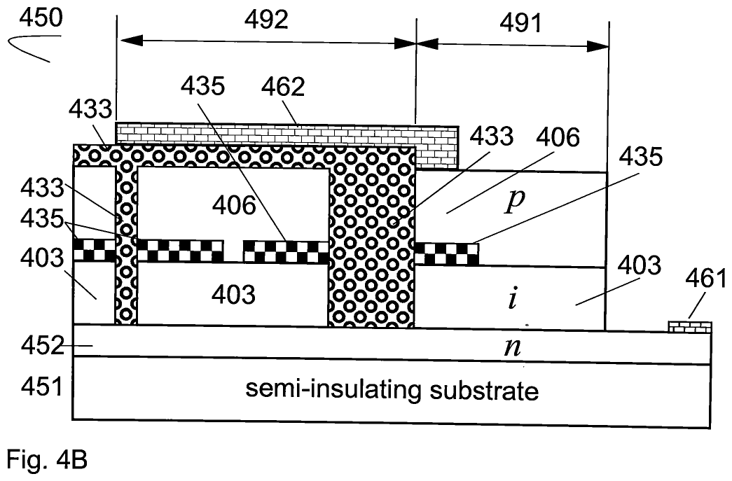

FIGS. 4A and 4B illustrate further embodiments of the present invention including special contact pads. FIG. 4A shows a device (400), according to another embodiment of the present invention, the device containing an n-doped (302), an undoped i-part (403), and a p-doped part (406). Holes are etched and filled by a dielectric (433) forming voids (435), according to the above-described process of FIGS. 3A through 3D. Dielectric (433) electrically isolates the active section of the device (441) from the passive section of the device (442). The passive sections (442) in FIG. 4A can be used as matching electric circuits. Such a circuit can be processed under the pad (412) to provide necessary effective circuit parameters R, C and L to minimize back reflections of a high frequency electric signal, as it is explained in the non-patent publication by Molchanov and Makarov, “Phenomenological Method for Broadband Electrical Matching of Acousto-optical Device Piezotransducers”, Optical Engineering, volume 38, issue 7, pages 1127-1135, 1 Jul. 1999, https://www.doi.org/10.1117/1.602162, wherein the publication is hereby incorporated herein in its entirety by reference.

FIG. 4B illustrates a device (450), according to yet another embodiment of the present invention, wherein the device is grown on a semi-insulating substrate (451). The n-contact (461) is mounted on top of the n-doped layer (452). The device (450) contains the active section (491) and the passive section (492). The dielectric pattern is formed on top of the semiconductor structure fully electrically isolated from the p-n junction device allowing ultimately low capacitance of the pad (462).

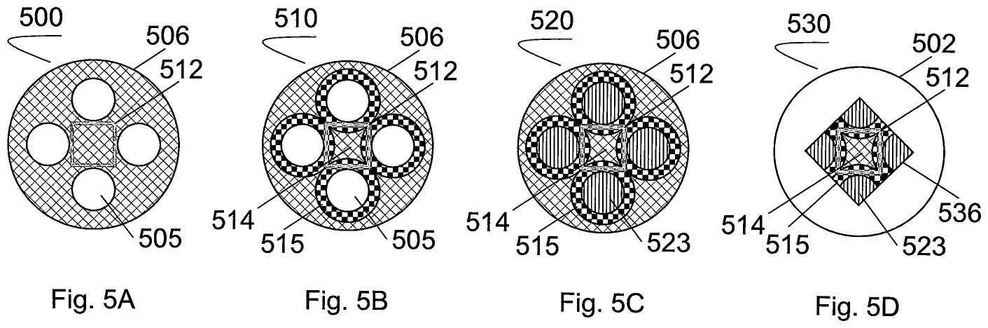

FIGS. 5A through 5D illustrate a possible device processing route illustrated from top. FIG. 5A shows the stage (500), wherein holes (505) are etched, and the p-contact (512) is mounted on the top surface (506).

FIG. 5B shows the next stage (510), where voids (515) are formed around the holes (505), the voids (515) laterally confine the aperture (514).

FIG. 5C refers to the next stage (520), wherein the holes (505) are filled by a dielectric (523).

FIG. 5D describes the next stage (530), where the excessive material is removed, forming the mesa (536).

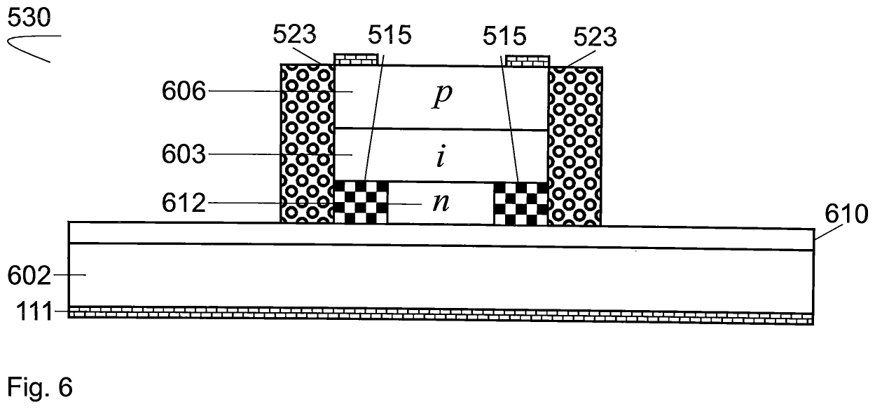

FIG. 6 represents the vertical cross-section of the device shown in FIG. 5D. The device contains the In(x)Ga(1−x)As-based p-section (606), the In(x)Ga(1−x)As-based undoped active region (603), the n-doped InP-based part (612), the In(x)Ga(1−x)As etch-stop layer (610), the structure being grown on an InP-substrate (602). Various dielectrics (523) can be applied for filling the holes, including, but not limited to Si(x)N(y), AlO(y), benzocyclobutene (BCB), polyamide, polyimide, etc.

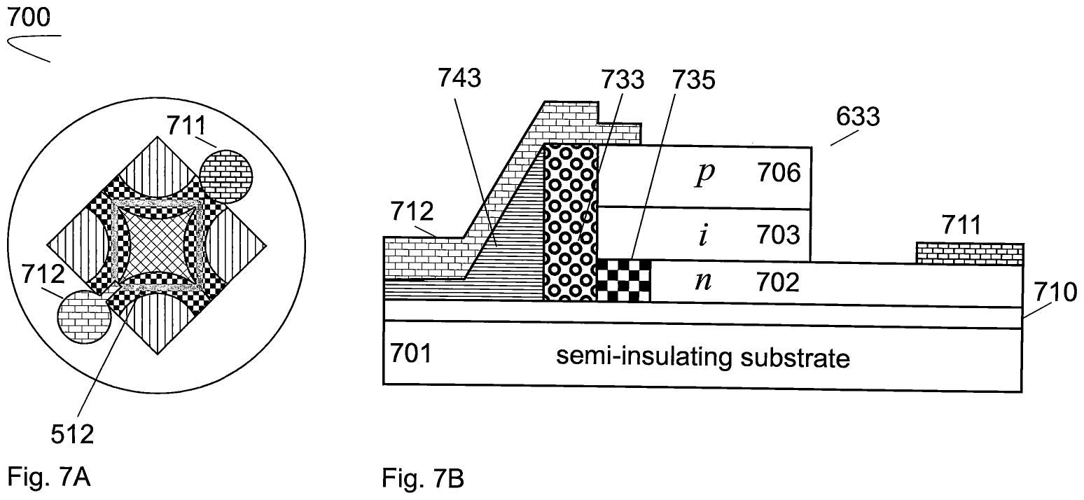

FIGS. 7A and 7B illustrate the top view and the cross-section of the device (700) grown on a semi-insulating substrate (701), further showing placement of the n-contact pad (711) and p-contact pad (712). The structure includes the etch-stop layer (710), n-doped section (702), undoped active section (703), and the p-doped section (706). The dielectrics (733) and (743) as well as the shape of the p-contact pad (712) are optimized to minimize the device capacitance.

One should emphasize that the placement of apertures directly at the active region is disadvantageous for light emitting devices, as defects can be generated at the interface due to a high concentration of nonequilibrium carriers that recombine non-radiatively at the interface states and release energy capable of breaking chemical bonds in the crystal lattice. Using doped separating layers increases depletion capacitance and enables current flow parallel to the oxide interface leading to electromigration of weakly bound oxygen atoms from residual As—O and Ga—O phases dissolved in the oxide aperture. Similar processes occur in etched aperture regions. The electromigration of oxygen atoms towards the active region would deteriorate the performance of the device.

The present invention discloses an approach for solving the problem by applying undoped intermediate layers in combination with induced doping. The intermediate layer is located between the aperture layer and the undoped active region. The aperture layer is doped, and the intermediate layer is initially undoped. However, a doped aperture layer can lead to induced doping of the adjacent initially undoped layer. Then, a part of the initially undoped layer (in the vicinity of the aperture) contains mobile carriers and is electrically conducting. At the same time the rest of the initially undoped layer remains undoped. All this results in a reduction of the surface area of the p-n junction and, thus, in a reduction of the device capacitance.

One should note that a layer regarded as an undoped layer still can be unintentionally doped and contain some residual doping level. It is preferred that the unintentionally doped layers in the devices all have residual doping not exceeding 5E16 cm⁻³.

A one skilled in the art will appreciate that an interface between a semiconductor layer and a dielectric layer or between a semiconductor layer and a void typically contain deep centers capable of localizing carriers. Thus, if a layer is intentionally weakly doped (i.e. p-doped), and a product of the doping level p and the layer thickness d is less than the surface concentration of deep centers at the interface,

$$p d < {N}_{i nterface} , \qquad ( 1 )$$

then all carriers are trapped at the deep centers, and the layer becomes effectively undoped. In practical devices, a weakly doped layer below the doping level 5E17 cm⁻³ can thus become effectively undoped.

Consequently, after the oxidation (or formation of voids) the region of the aperture is electrically insulating but also the undoped region around the aperture is insulating. As opposite in the region where the aperture layer is not removed or oxidized the conductivity is enabled by the doped aperture and the induced doping (or modulation doping) effect resulting in mobile carriers in the undoped regions.

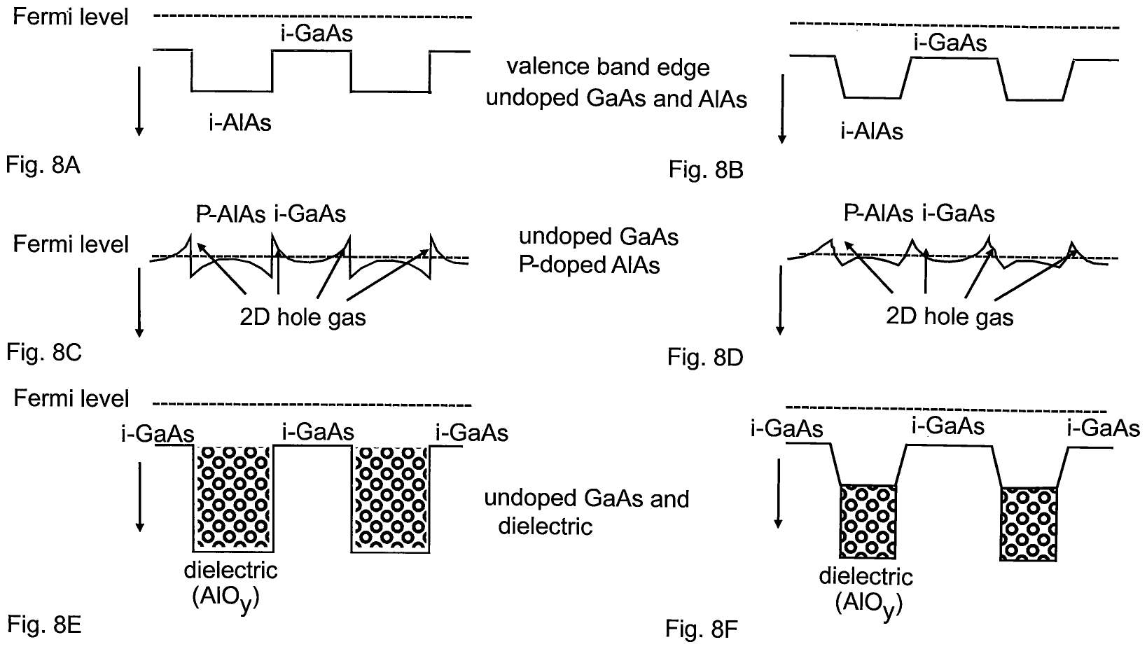

The effect of induced doping of initially undoped layers is addressed in FIGS. 8A through 8F.

FIG. 8A represents the valence band diagram for the valence band of undoped multilayer heterostructure on an example of AlAs—GaAs materials with abrupt interfaces.

FIG. 8B shows the valence band diagram for the valence band of undoped multilayer heterostructure on an example of the same AlAs—GaAs materials with graded interfaces.

FIG. 8C depicts the valence band diagram for the valence band of modulation doped multilayer heterostructure on an example of AlAs—GaAs materials, whereas only AlAs layers are p-doped with an acceptor impurity, and GaAs is undoped. The figure shows the case of abrupt interfaces. It is important to emphasize the key feature of the heterointerfaces between p-AlAs and i-GaAs. Due to the band alignment at the heterointerface, a two-dimensional hole gas is formed in the initially undoped layer of GaAs. Thus, initially undoped layer of GaAs becomes an induced doped layer allowing electric conductivity.

FIG. 8D represents valence band diagram for the valence band of modulation doped multilayer heterostructure on an example of AlAs—GaAs materials, whereas only AlAs layers are p-doped with an acceptor impurity, and GaAs is undoped. The figure shows the case of graded interfaces. It is again important to emphasize the key feature of the heterointerfaces between p-AlAs and i-GaAs. Due to the band alignment at the heterointerface, a two-dimensional hole gas is formed in the initially undoped layer of GaAs. Thus, initially undoped layer of GaAs becomes induced doped layer allowing electric conductivity.

A one skilled in the art will appreciate that the resulting doping level in the induced doped layer and, hence, the electric conductivity depends on the doping level of the adjacent doped aperture layer. In case of the p-doping the preferred doping level of the aperture layer is above 1E18 cm⁻³. More preferred is the doping level of the aperture layer is above 5E18 cm⁻³.

As regards the thickness of the induced doped layer, it may not be too thin to prevent propagation of the structural defects to the active region. On the other hand, it may not be too thick no enable the effective induced doping throughout the entire thickness of the layer. A one skilled in the art will agree that the thickness of this layer is preferably above 10 nm (ten nanometers). On the other hand, the thickness of the induced doped layer is preferably below 100 nm (one hundred nanometers).

FIG. 8E shows the valence band diagram for the valence band of modulation doped multilayer heterostructure on an example of AlAs—GaAs materials, wherein AlAs layers are selectively transformed to AlO_{y}. The figure refers to the case of abrupt interfaces.

FIG. 8F shows the valence band diagram for the valence band of modulation doped multilayer heterostructure on an example of AlAs—GaAs materials, wherein AlAs layers are selectively transformed to AlO_{y}. The figure implies the case of graded interfaces.

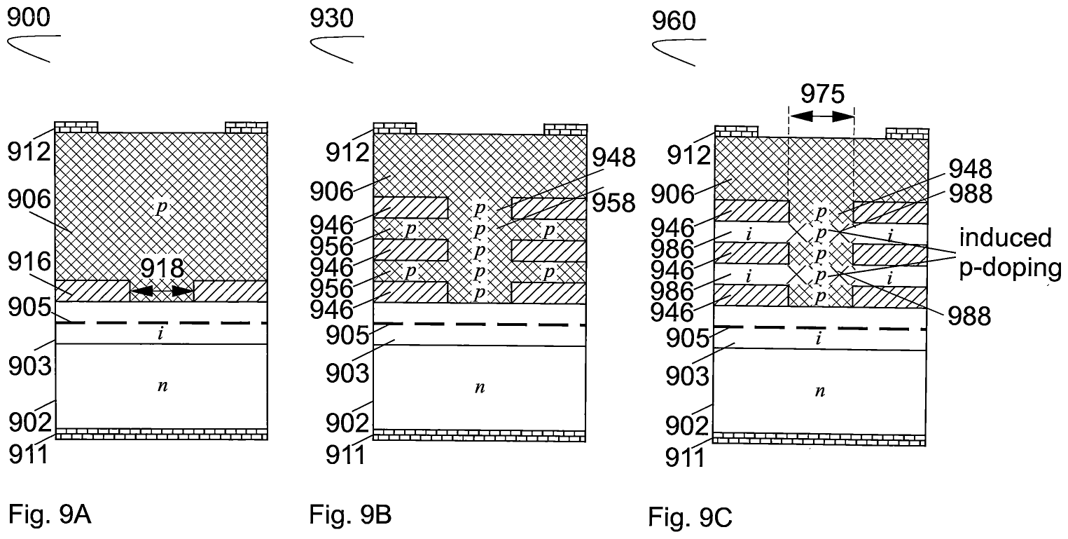

Several such aperture layers can be applied, as is shown in FIGS. 9A through 9C. In this case the whole multilayer aperture region can be extended further thus reducing the capacitance.

FIG. 9A shows the device (900) consisting of the n-doped part (902), the undoped part (903), inside of which the active medium (905) is placed, and the p-doped part (906). The n-contact (911) is mounted on the back side of the n-doped substrate, and the p-contact (912) is mounted on the top of the p-doped part (906). A single aperture layer is introduced, wherein a single oxide layer (916) is formed confining the aperture (918).

FIG. 9B depicts the device (930), containing three aperture layers. Upon oxidation, three oxide layers (946) are formed confining three apertures (948). Both the aperture layers (948) and the intermediate layers (956) between the aperture layers are p-doped.

FIG. 9C illustrates the device (960), according to an embodiment of the present invention, in which the intermediate layers (986) between the aperture layers are undoped. The neighboring p-doped aperture layers (948) lead to induced p-doping of the regions (988) of the intermediate layers (986). The induced doping is driven by band alignment at the heterointerface between the p-doped aperture layers (948) and initially undoped intermediate layers (986), as illustrated in FIGS. 8C and 8D. Thus, a conducting column (975) surrounded by isolated regions (986) is formed. As the rest part of initially undoped layers (986), besides the induced p-doped regions (988) remains undoped. Then the effective surface area of the p-n junction is determined by the area of the conducting column (975). This area is significantly reduced with respect to the initial surface area (determined by the mesa area). Correspondingly the device capacitance is strongly reduced.

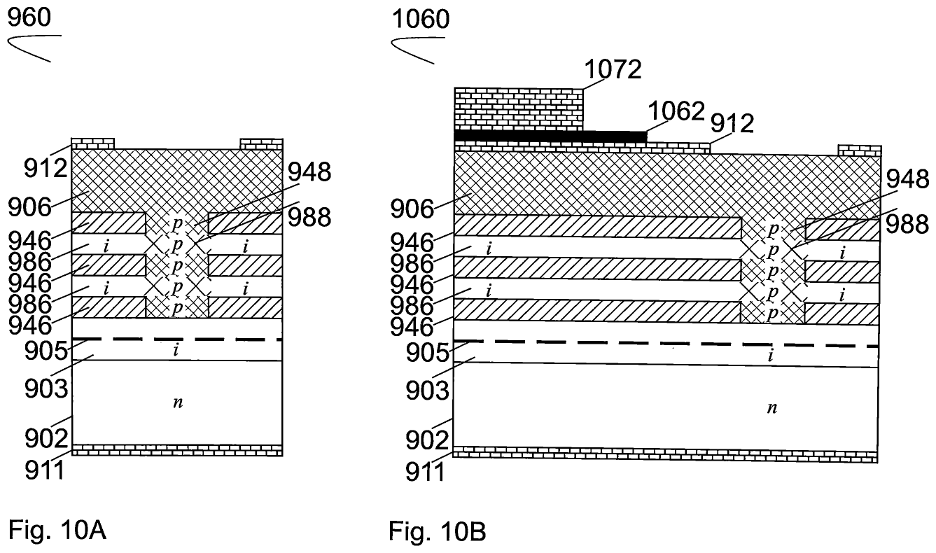

FIG. 10A depicts the single conducting column device with multiple isolated dielectric or void apertures, repeating FIG. 9C.

FIG. 10B shows a single conducting column device (1060) with multiple isolated dielectric or void apertures showing a possible arrangement of the contact pad directly on semiconductor without generation of significant capacitance. The interconnect (1062) is placed on top of the contact (912), and the contact pad (1072) is mounted on top of the interconnect (1062). No significant capacitance is introduced as the pad is placed above the undoped region.

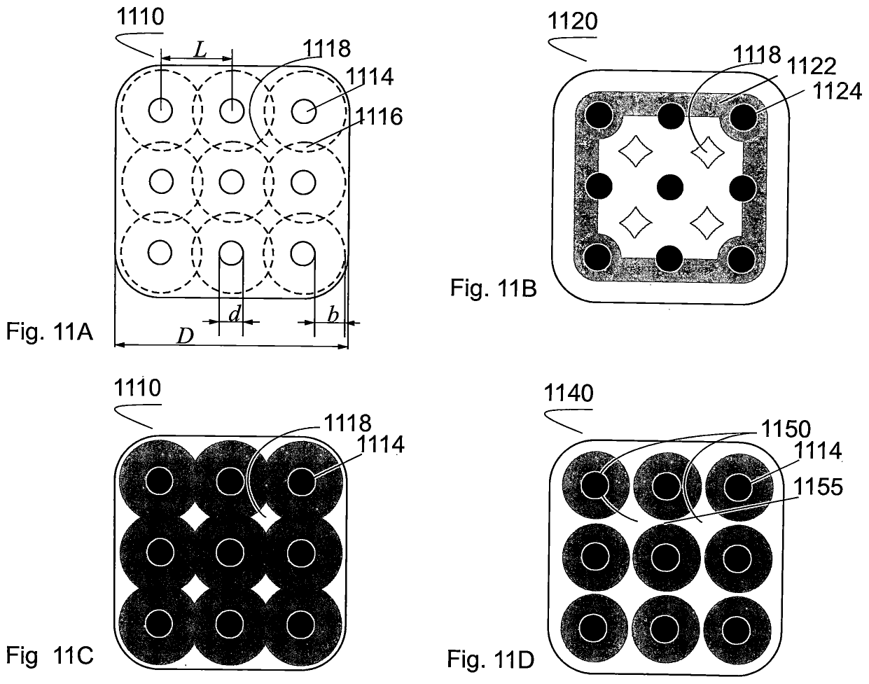

FIGS. 11A through 14E refer to multi-aperture arrays of optoelectronic devices disclosed in the parent patent application Ledentsov '041. The present invention focuses on the ultimate reduction of the capacitance in the various embodiments of multi-aperture arrays.

FIG. 11A shows schematically a miniarray (1110) of an embodiment of the present invention. Particularly, FIG. 11A shows a cross-section in the plane parallel to the lateral plane, the plane of the cross section being the plane of the layer subject to oxidation. The mesa has the shape of a square D×D with rounded corners. The mesa contains a 3×3 array of openings (1114), the centers of the neighboring openings are placed at a distance L from each other. Each of the openings has a circular shape with a diameter d. The process of the selective oxidation results in the oxidation of the areas of the layer subject to oxidation over a depth of b. A skilled in the art will appreciate that once the oxidation of the layer or layers of AlAs or Ga(1−x)Al(x)As is performed in the atmosphere of the water vapor, the oxidation depth can be controlled by the temperature in the reactor, by the vapor pressure, by the aluminum composition in the layers, by the layer thickness and by the duration of the process. The oxidation depth is preferably selected such that

$$d + 2 b > L . \qquad ( 2 )$$

Then the oxidized areas, originating from neighboring openings, overlap (1116). Thus, four separated non-oxidized areas (apertures) (1118) are formed.

FIG. 11B illustrates the cross-section in the lateral plane of an miniarray of VCSELs (1120), according to another embodiment of the present invention, wherein the etching depth of the holes (1124) is smaller than the thickness of the top DBR of the VCSEL, such that the layer subject to selective oxidation is not etched, and the oxidation proceeds only from the side of the mesa forming an oxide layer at the mesa perimeter (1222).

FIG. 11C illustrates schematically the same cross-section of the structure (1110) in the plane parallel to the lateral plane. The openings filled by a dielectric are marked black (1114), the oxidized areas are gray, and the non-oxidized areas (apertures) are white (1118). In the embodiment of FIGS. 11A, 11C, and 11D the apertures are diamond-shaped.

FIG. 11D illustrates schematically the same cross-section (1140) of the structure in the plane parallel to the lateral plane, according to yet another embodiment of the present invention. The oxidized areas originating from the neighboring holes do not overlap. Thus, the neighboring apertures (1150) are connected to each other. Despite such connections, each of the apertures is capable to confine an optical mode in the lateral plane. The lateral dimensions of the bottlenecks, or bridges (1155) connecting the neighboring apertures govern the coupling strength between the neighboring apertures.

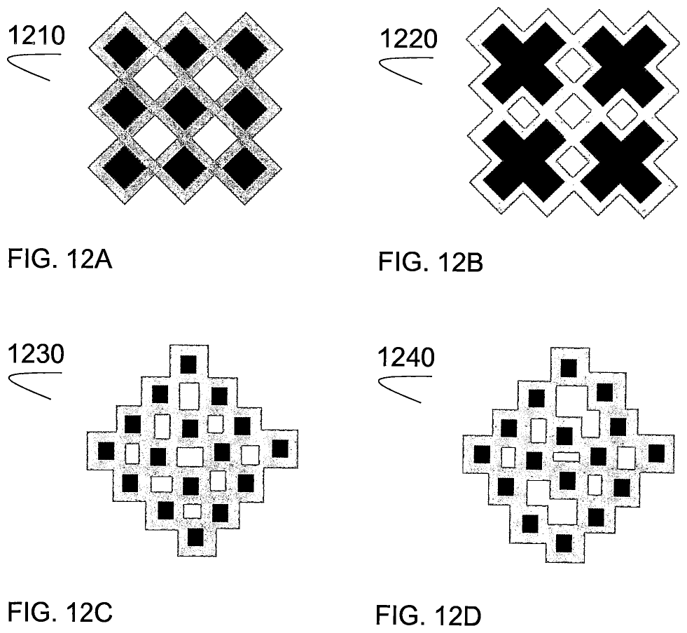

FIGS. 12A through 12D illustrate different embodiments of the present invention. FIG. 12A refers to an embodiment (1210) with square-shaped openings and square shaped apertures.

FIG. 12B illustrates a miniarray (1220) with five apertures.

FIG. 12C illustrates yet another embodiment (1230) of the present invention with low-symmetry apertures shapes.

FIG. 12D illustrates a further embodiment (1240) of the present invention with low-symmetry apertures shapes.

For example, elongated aperture shapes are advantageous to obtain a linearly polarized lasing.

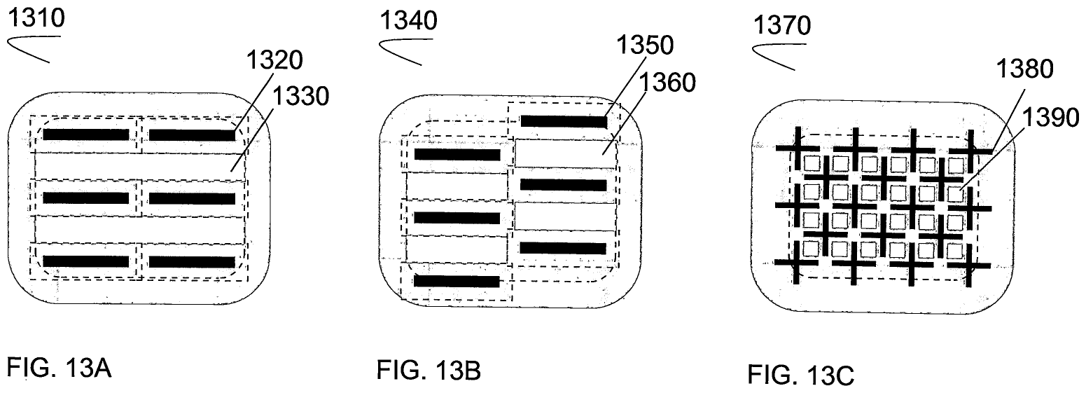

FIG. 13A illustrates schematically a cross-section in a lateral plane of a miniarray (1310) of VCSELs, according to an embodiment of the present invention. The holes (1320) are elongated, and, thus, the non-oxidized areas form apertures (1330) having a shape of elongated stripes.

FIG. 13B illustrates schematically a cross-section in a lateral plane of a miniarray (1340) of VCSELs, according to another embodiment of the present invention. The elongated holes (1350) are shifted with respect to each other resulting in elongated apertures (1360) shifted with respect to each other. An optical mode formed in each of the apertures can be coupled with an optical mode formed in a neighboring aperture, the coupling occurring via the corners of the apertures.

FIG. 13C illustrates schematically cross-section in a lateral plane of a miniarray (1370) of VCSELs, according to yet another embodiment of the present invention. Holes (1380) have the shape of crosses, whereas the apertures (1390) are square-shaped.

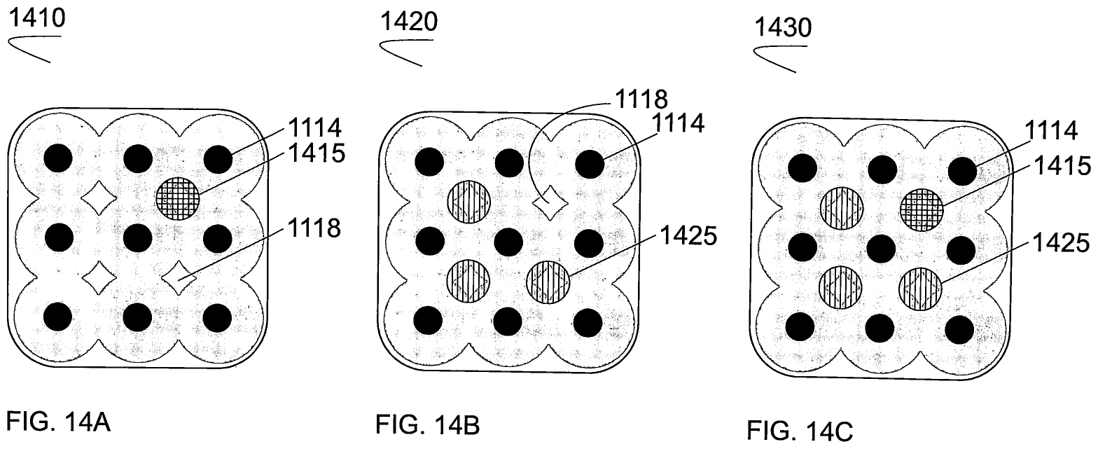

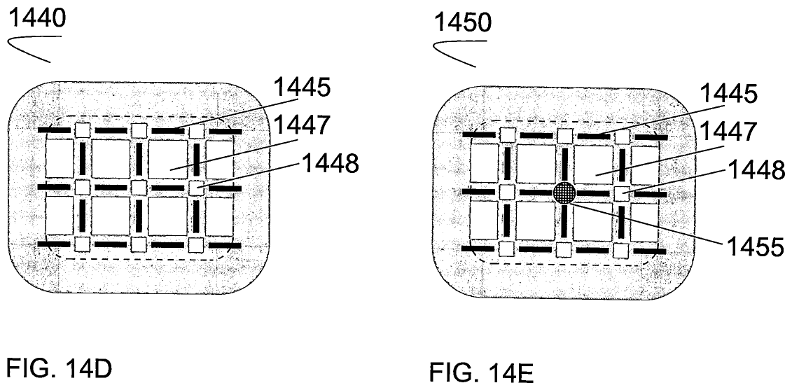

FIG. 14A through 14C illustrates schematically a practical realization of a miniarray of VCSELs according to various embodiments of the present invention. FIG. 14A illustrates a miniarray (1410) of VCSELs according to an embodiment of the present invention, in which one of the apertures is covered by a highly reflecting dielectric coating (1415) forming one mode having a higher finesse versus a lower finesse of the rest three modes.

FIG. 14B illustrates a miniarray (1420) of VCSELs according to another embodiment of the present invention, in which three apertures are covered by anti-reflective coatings (1425) forming three modes having a lower finesse compared to a single mode with a higher finesse related to an uncovered aperture.

FIG. 14C illustrates a miniarray (1430) of VCSELs according to yet another embodiment of the present invention, in which one aperture is covered by a highly reflecting coating (1415), whereas the other three apertures are covered by anti-reflective coatings (1425), thus combining the features of the embodiments of FIGS. 14A and 14B.

FIG. 14D illustrates schematically a miniarray (1440) of VCSELs according to further embodiment of the present invention, whereas the holes (1445) have elongated shape, and apertures form a checkerboard array of alternating apertures having a larger area (1447) and apertures having a smaller area (1448).

FIG. 14E illustrates schematically a miniarray (1450) of VCSELs according to another embodiment of the present invention, whereas a highly reflective coating (1455) is deposited over one of the apertures having a smaller area (1448).

A remarkable property of multi-aperture arrays of VCSELs is a self-injection locking effect, observed in the non-patent publication by Lindemann et al., “Study of Electrically Excited Photon-Photon Resonances in Self-Injection-Locked Coupled-Cavity VCSELs”, 2024 IEEE 29th International Semiconductor Laser Conference (ISLC), Orland, FL, USA, pp. 1-2, https://doi.org/10.1109/ILC57752.2024.10717381, wherein the publication is hereby incorporated herein in its entirety by reference.

In the case of a two-aperture miniarray of VCSELs, the self-injection locking effect manifests itself by the interaction of two coupled optical modes via the electron-hole plasma in the active medium, wherein one of the coupled modes is suppressed and the single-mode lasing occurs. The self-injection locking effect can be controlled by the geometry of a multi-aperture miniarray of VCSELs. Applying a multi-aperture miniarray of VCSELs with a number of apertures above two gives more possibilities to control the effect.

A further remarkable property of a miniarray of optically coupled VCSELs was observed and reported in the non-patent publication by Lindemann, et al., “Coupled Aperture VCSELs Suitable for 100 GHz Intensity Modulation”, 2023 23rd International Conference on Transparent Optical Networks (ICTON), Bucharest, Romania, 2023, pp. 1-4, https://www.doi.org/10.1109/ICTON59386.2023.10207536, wherein this publication is hereby incorporated herein in its entirety by reference. Once a two-aperture miniarray of optically coupled VCSELs emits laser light in 2 optically coupled modes, the emission intensity detected separately from each of the apertures, oscillates out-of-phase by π (in anti-phase) with the observed oscillation frequency up to 75 GHz. Once only the emission from one aperture out of two apertures is coupled to an optical fiber, the fiber transmits an optical signal with a high frequency modulated amplitude, which can be employed for Radio over fiber (RoF) applications.

Another remarkable property of a miniarray of optically coupled VCSELs manifests itself in a regime, different from self-injection locking. Once lasing in a miniarray occurs in multiple modes, beat frequencies in THz-range were observed, up to 300 GHz. These observations were reported in a non-patent publication by Hu et al., “Coherent CW Terahertz generation with a coupled-cavity mini-array VCSEL”, Electronics Letters, volume 61, issue 1, January/December 2025, https://ietresearch.onlinelibrarv.wiley.com/doi/pdf/10.1049/e112.70146, wherein the publication is hereby incorporated herein in its entirety by reference. Once two optical signals with a frequency difference in THz-range reach a photodetector, the photodetector generates electric signal at the beat frequency. Thus, miniarrays of optically coupled VCSELs can be applied for generation of high frequency electric signals in the range of hundreds of GHz through THz range. Since the optical field in two coupled apertures oscillates coherently and exactly in anti-phase, this approach allows to generate a high-quality high frequency electrical signal at a frequency 100 GHz and above.

Yet another remarkable property of a miniarray of optically coupled VCSELs, each of which is electrically addressed separately, is a possibility to control the lasing optical mode or several optical modes and to realize beam steering.

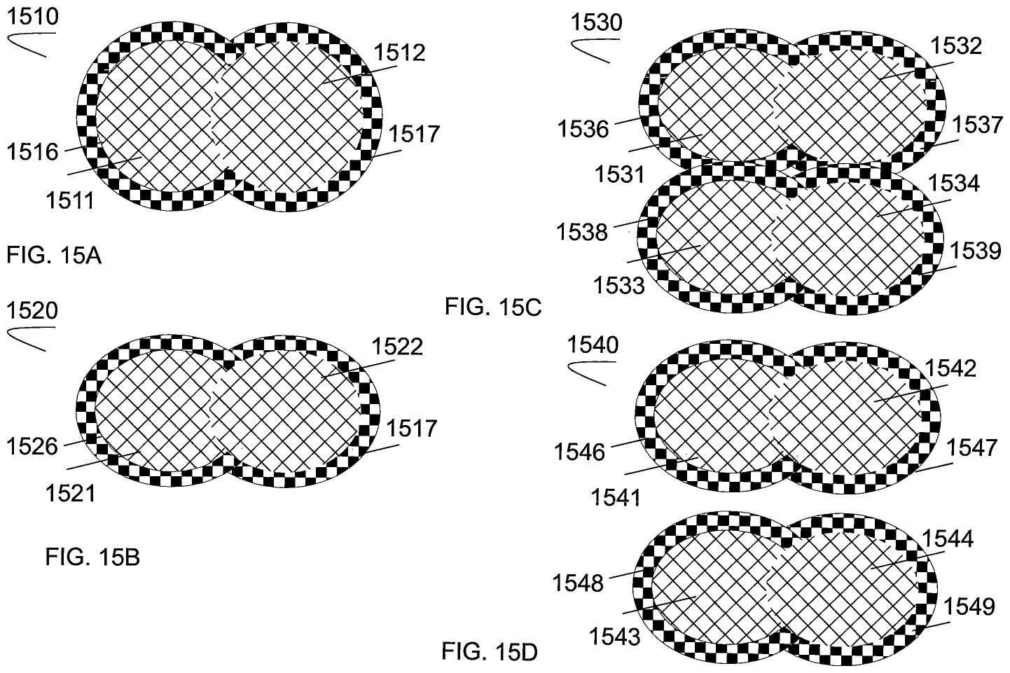

FIGS. 15A through 15D illustrate schematically top view of various multi-aperture miniarrays of VCSELs, where the apertures are optically coupled and suitable for phase injection locking or single mode self-injection locking aimed at the broadening of the modulation bandwidth.

FIG. 15A illustrates schematically a miniarray of VCSELs (1510) containing two circular apertures (1511) and (1512). The aperture (1511) is laterally confined by the oxidized part (1516) of the aperture layer. The aperture (1512) is laterally confined by the oxidized part (1517) of the aperture layer.

FIG. 15B illustrates schematically a miniarray of VCSELs (1520) containing two oval apertures (1521) and (1522). The aperture (1521) is laterally confined by the oxidized part (1526) of the aperture layer. The aperture (1522) is laterally confined by the oxidized part (1527) of the aperture layer.

FIG. 15C illustrates schematically a miniarray of VCSELs (1530) containing four closely spaced oval apertures (1531), (1532), (1533) and (1534). The aperture (1531) is laterally confined by the oxidized part (1536) of the aperture layer. The aperture (1532) is laterally confined by the oxidized part (1537) of the aperture layer. The aperture (1533) is laterally confined by the oxidized part (1538) of the aperture layer. The aperture (1534) is laterally confined by the oxidized part (1539) of the aperture layer.

FIG. 15D illustrates schematically a miniarray of VCSELs (1540) containing four oval apertures (1541), (1542), (1543) and (1544). The first group of apertures, namely apertures (1541) and (1542) are closely placed to each other. The second group of apertures, namely apertures (1543) and (1544) are closely placed to each other. The lateral distance between the two groups is larger than the spacing inside each of the groups. The aperture (1541) is confined by the oxidized part (1546) of the aperture layer. The aperture (1542) is confined by the oxidized part (1547) of the aperture layer. The aperture (1543) is laterally confined by the oxidized part (1548) of the aperture layer. The aperture (1544) is laterally confined by the oxidized part (1549) of the aperture layer.

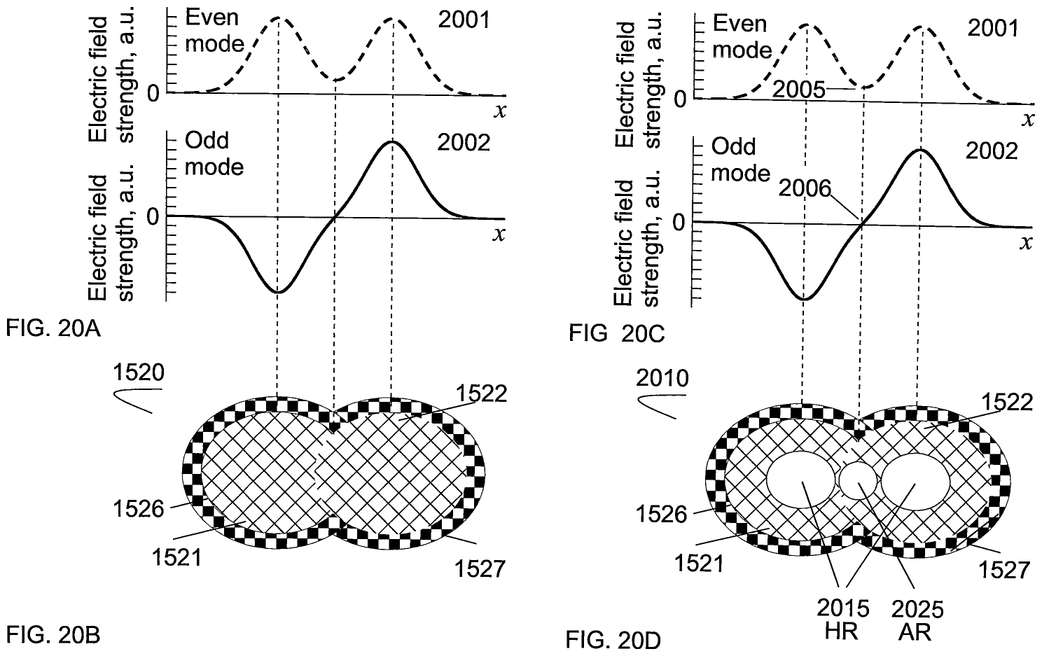

FIGS. 20A through 20D illustrate another embodiment of the present invention, referring to a two-aperture miniarray of VCSELs. FIG. 20A depicts the electric field profiles of the even coupled mode (2001) and odd coupled mode (2002). Such coupled modes that combine the modes originating from individual apertures, can also be called supermodes.

FIG. 20B repeats FIG. 15B of a two-aperture miniarray of VCSELs for convenience. A one skilled in the art will appreciate that each of the apertures considered individually, has a single non-degenerate fundamental optical mode due a non-circular, but oval shape of the aperture. Thus, the relevant coupled modes are just two supermodes coupling the modes originating from the individual apertures.

FIG. 20C repeats the two optical mode profiles of FIG. 20A, further pointing out the zero of the electric field of the odd mode (2006) and a non-zero value of the electric field of the even mode (2005), in the region between two apertures.

FIG. 20D shows a two-aperture miniarray of VCSELs (2010), according to an embodiment of the present invention, whereas highly reflecting (HR) coatings (2015) are deposited in the central parts of the apertures (1521) and (1522), and an anti-reflective (AR) coating (2025) is deposited in the central part of the miniarray. While the odd mode (2002) has zero amplitude (2006) in the central part of the miniarray, it is insensitive to the AR coating (2025). On the contrary, the even mode (2001) has a non-zero amplitude (2005) in the central part, and the AR coating (2025) increases the losses of the even mode (2001). Thus, the proposed combination of HR (2015) and AR (2025) coatings suppresses the even mode (2001) thus supporting single-mode lasing in the odd mode (2002).

In another embodiment of the present invention, a diffraction grating can be deposited on top of a part of the top surface of a miniarray of VCSEL aimed at mode selection and promoting self-injection locking regime.

In yet another embodiment, certain sections on the top surface of a miniarray of VCSELs can be etched off.

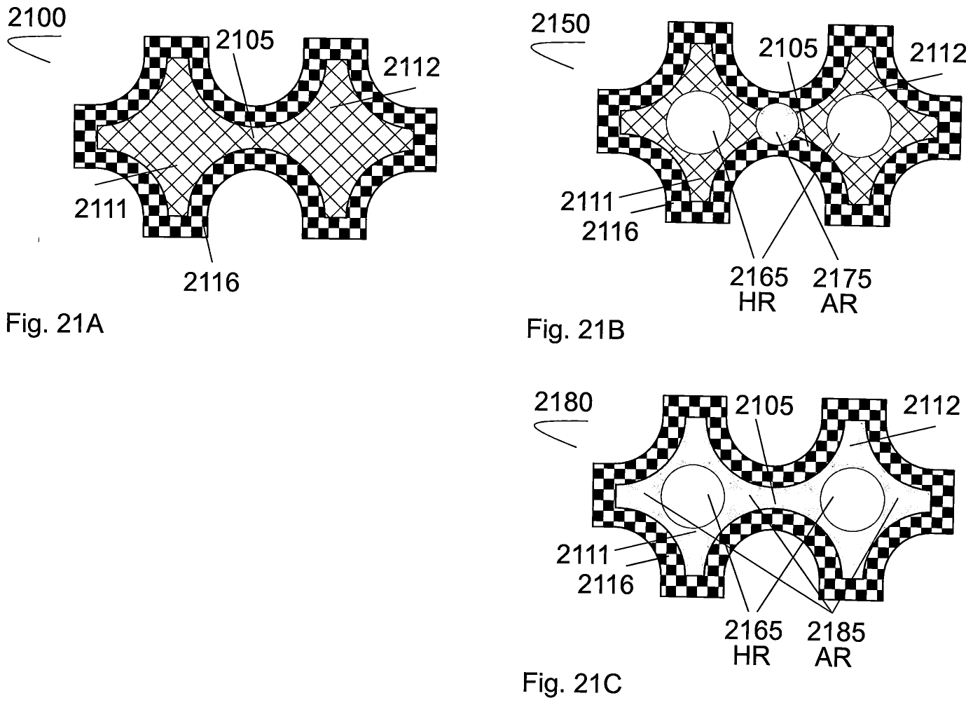

FIG. 21A shows a two-aperture miniarray of VCSELs (2100) according to an embodiment of the present invention. Each of the apertures (2111) and (2112) has a diamond shape which can be formed by the oxidation from the holes, as shown in connection to the embodiments on FIGS. 11A, 11C, and 11D. The two diamond-shape apertures are connected by a narrow bridge (2105). The parts of the oxide layer confining the apertures have shapes of sectors of a ring (2116). The two coupled apertures of FIG. 21A have together a bow-tie shape.

FIG. 21B shows a two-aperture miniarray of VCSELs (2150) according to another embodiment of the present invention. Highly reflecting (HR) coatings (2165) are deposited on the central parts of the diamond-shape apertures (2111) and (2112), and an anti-reflective (AR) coating (2175) is deposited on the bridge (2105). Similarly to the embodiment of FIG. 20D, the coatings promote single mode lasing in the odd optical mode.

In yet another embodiment of the present invention, a hole can be locally etched at the bridge (2105) aimed to enhance optical losses of the even optical mode, whereas the odd optical mode vanishing at the bridge remains unsensitive to the etched hole. This will additionally promote self-injection locking and single mode lasing of the VCSEL miniarray.

FIG. 21C shows a two-aperture miniarray of VCSELs (2180) according to a further embodiment of the present invention. Highly reflecting (HR) coatings (2165) are deposited on the central parts of the diamond-shape apertures (2111) and (2112), and an anti-reflective (AR) coating (2185) is deposited everywhere else on the surface of the miniarray. The combination of two coatings supports single mode lasing in the odd optical mode.

Further to the consideration of the optical properties of multi-aperture VCSELs (or miniarrays of VCSELs), in connection to the embodiments of FIGS. 11A through 15D and of FIGS. 20A through 21D, the present invention discloses various approaches to ultimately reduce the capacitance of these miniarrays.

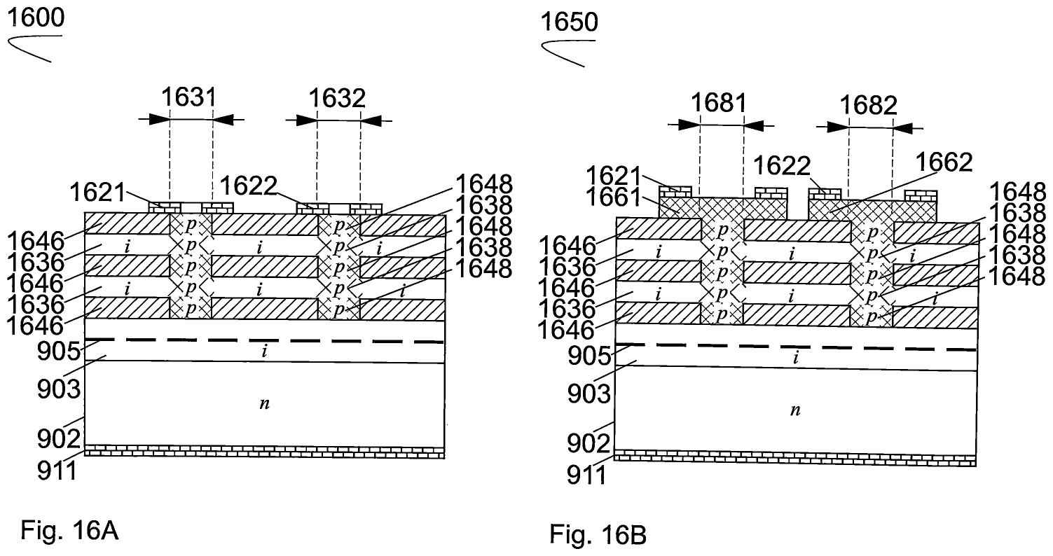

FIG. 16A shows a cross section in the vertical plane of an array (1600) with several apertures wherein each aperture is contacted by individual electric contact, according to an embodiment of the present invention. The device contains several aperture layers, which form, upon oxidation, layers of oxide (1646) separated by the undoped layers (1636). The non-oxidized apertures (1648) are p-doped which results in induced p-doping of the sections (1638) of the initially undoped layers (1636). Thus, conducting columns are formed, two of which, (1631) and (1632) are shown in FIG. 16A. The contact (1621) is formed on the top of the column (1631), and the contact (1622) is formed on the top of the column (1632). The two contacts are formed immediately on top of one p-doped aperture layer (1648). The two contacts are electrically isolated which allows to contact electrically individually the column (1631) and the column (1632), thus the two neighboring apertures and, respectively, the two neighboring conducting columns are two devices in the array (1600). It should be emphasized that the effective area of the p-n junction in each of the devices in the array is determined by the area of the induced p-doped parts (1638) of the initially undoped layers (1636), i.e., by the surface area of the conducting columns (1631) and (1632). This area is significantly reduced with respect to the initial area of the p-n junction determined by the mesa area. Correspondingly, the device capacitance is significantly reduced.

FIG. 16B shows a cross-section in the vertical plane of an array (1650), with several apertures wherein each aperture is contacted by individual electric contact, according to another embodiment of the present invention. The p-doped layer (1661) is grown on top of the topmost p-doped aperture layers (1648), and the p-contact (1621) is mounted on top of the layer (1661) to contact the conducting vertical column (1681). The p-doped layer (1662) is grown on top of the topmost p-doped aperture layer (1648), and the p-contact (1622) is mounted on top of the layer (1662) to contact the conducting vertical column (1682). The two conducting vertical columns are electrically isolated. It should be emphasized that the effective area of the p-n junction in each of the devices in the array is determined by the area of the induced p-doped parts (1638) of the initially undoped layers (1636), i.e., by the surface area of the conducting columns (1681) and (1682). This area is significantly reduced with respect to the initial area of the p-n junction determined by the mesa area. Correspondingly, the device capacitance is significantly reduced.

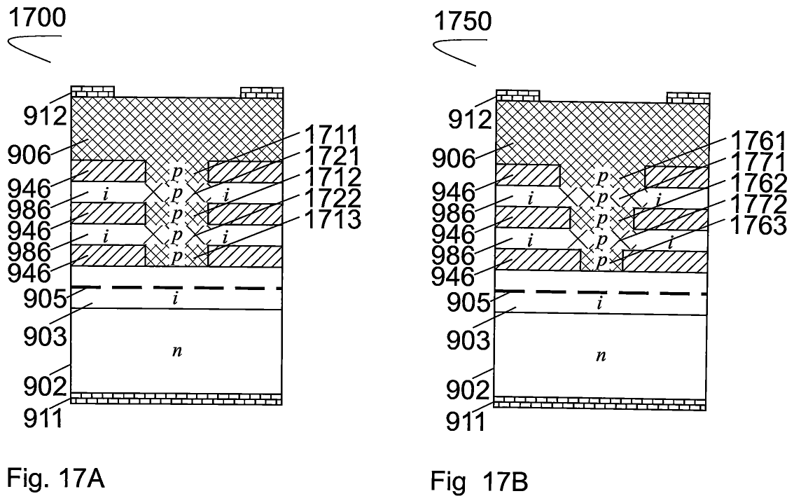

FIGS. 17A and 17B illustrate a device, according to yet another embodiment of the present invention. The device (1700) in FIG. 17A is basically the same as the device (960) in FIG. 9C. However, here the focus is given that the lateral dimensions of the apertures (1711), (1712) and (1713) as well as the lateral dimensions of the induced p-doped parts (1721) and (1722) of initially undoped layers (986) are the same throughout the structure.

Device (1750) in FIG. 17B contains the sequence of p-doped aperture (1761), induced p-doped part (1771) of the initially undoped layer (986), p-doped aperture (1762), induced p-doped part (1772) of the initially undoped layer (986), p-doped aperture (1763) have lateral dimensions that decrease from the top to the bottom of the structure of the device (1750). This can be achieved by configuring the layers subject to oxidation such that different layers, e.g., of Ga(1−x)Al(x)As have different aluminum composition and/or different thickness. Then, upon oxidation, the thickness of the oxidized regions of the corresponding layers will be different.

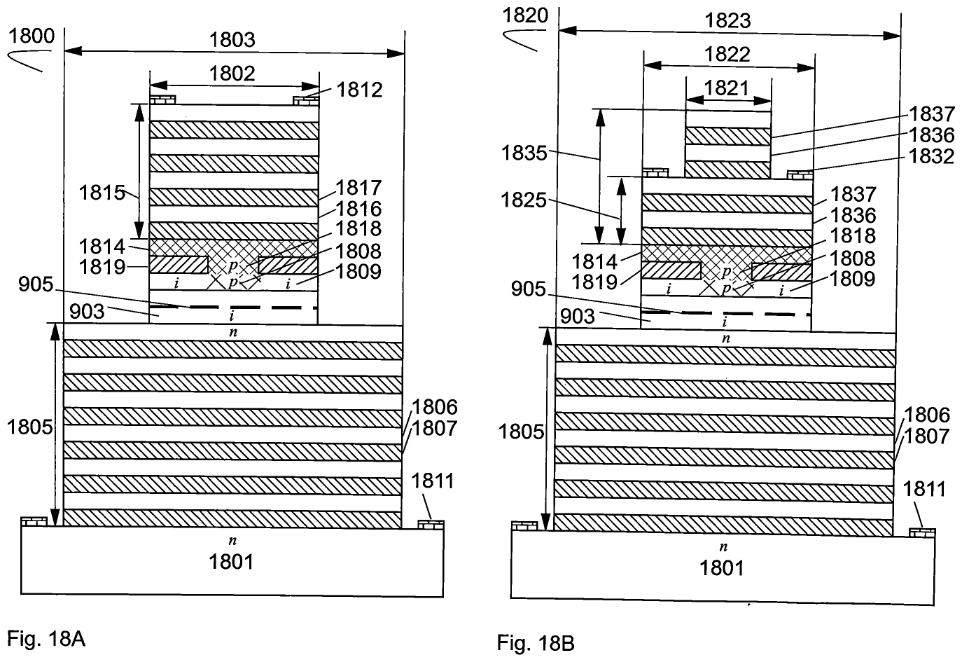

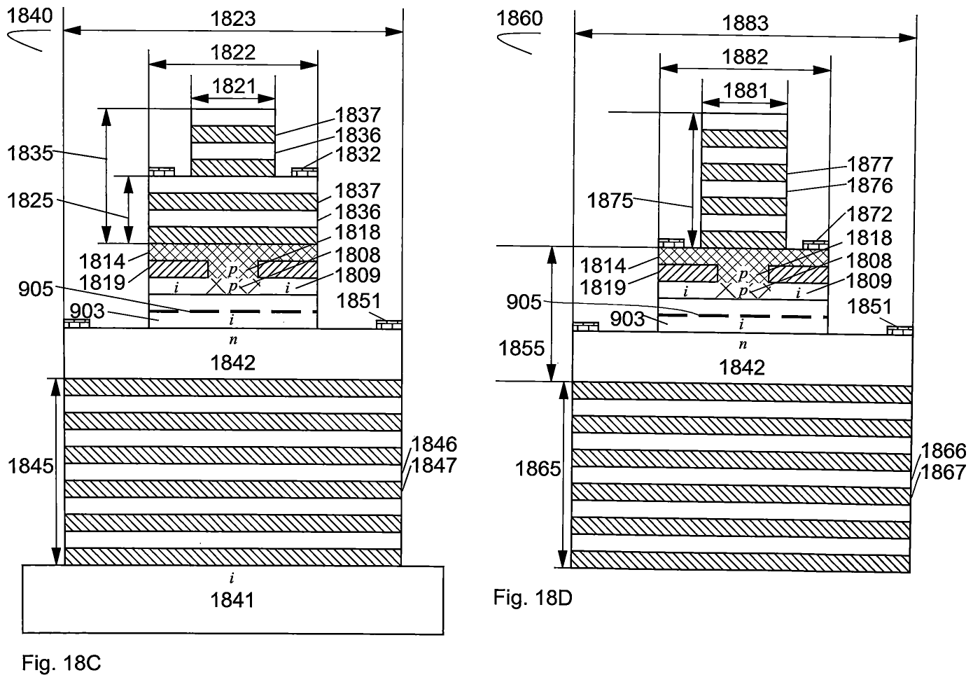

FIG. 18A shows schematically a cross-section in the vertical plane of the VCSEL (1800), according to an embodiment of the present invention. The structure is grown on top of an n-doped buffer layer (1801), which is grown on top of a substrate (not shown). The VCSEL contains an undoped cavity (903) with an active region (905) positioned between a bottom DBR (1805) and a top DBR (1815). The bottom DBR (1805) contains a sequence of layers with alternating high (1806) and low (1807) refractive index. The top DBR (1815) contains a sequence of layers with alternating high (1816) and low (1817) refractive index. The bottom (n) contact (1811) is mounted on top of the n-doped buffer layer (1801). The top (p) contact (1812) is mounted on top of the top surface of the top DBR (1815). The layer (1814) is a p-doped layer between the aperture layer (1818) and the periodic top DBR (1815).

The VCSEL chip (1800) contains a first mesa (1802) etched down to the n-doped part of the structure and a second mesa (1803) etched down to the buffer layer (1801). Initially, the surface area of the p-n junction was determined by the surface area of the mesa (1802).

The aperture (1818) is p-doped and confined in the lateral plane by an oxide (1819). The layer (1809) between the p-doped aperture (1818) and undoped active region (903) is initially undoped. A high doping level in the aperture (1808) results in an induced doping in the part (1808) of the initially undoped layer. At the same time, the part of the layer (1809) outside (1808) remains undoped. The area of the p-n junction is now determined by the area of the induced doped (1808) part of the layer (1809). This area is significantly reduced with respect to the area of the mesa (1802). Thus, the device capacitance is reduced accordingly.

FIG. 18B shows schematically a cross-section in the vertical plane of the VCSEL (1820), according to another embodiment of the present invention. The top DBR (1835) is partially etched. The top contact (1832) is realized as an intracavity contact, mounted at an intermediate height of the top DBR (1835), on top of the part (1825) of the top DBR (1835). The part (1825) of the top DBR (1835) and the p-doped layer (1814) serve for current spreading. The top DBR (1835) consists of a sequence of layers with alternating high (1836) and low (1837) refractive index.

The VCSEL chip (1820) contains a first mesa (1821) etched down to an intermediate level in the top DBR (1835). The second mesa (1822) is etched down to the n-doped part of the structure. The third mesa (1823) is etched down to the buffer layer (1801). Initially, the surface area of the p-n junction was determined by the surface area of the mesa (1822).

Similarly, to the embodiment of FIG. 18A, the aperture (1818) of the VCSEL (1820) is p-doped and confined in the lateral plane by an oxide (1819). The layer (1809) between the p-doped aperture (1818) and undoped active region (903) is initially undoped. A high doping level in the aperture (1808) results in an induced doping in the part (1808) of the initially undoped layer. At the same time, the part of the layer (1809) outside (1808) remains undoped. The area of the p-n junction is now determined by the area of the induced doped (1808) part of the layer (1809). This area is significantly reduced with respect to the area of the mesa (1822). Thus, the device capacitance is reduced accordingly.

FIG. 18C shows schematically a cross-section in the vertical plane of the VCSEL (1840), according to yet another embodiment of the present invention. The structure contains both n-contact (1851) and p-contact (1832) as intracavity contacts. The structure is grown in a semi-insulating substrate (1841) and contains a bottom DBR (1845), that can be made undoped, the cavity, and the top DBR (1835). The bottom DBR (1845) is formed of a sequence of layers with alternating high (1846) and low (1847) refractive index. The n-doped layer (1842) grown on top of the bottom DBR (1845) serves as n-current spreading layer. The n-contact (1851) is mounted on top of the current spreading layer (1842).

The VCSEL chip (1840) contains a first mesa (1821) etched down to an intermediate level in the top DBR (1835). The second mesa (1822) is etched down to the n-doped part of the structure. The third mesa (1823) is etched down to the buffer layer (1801). Initially, the surface area of the p-n junction was determined by the surface area of the mesa (1822).

Similarly, to the embodiments of FIG. 18A and FIG. 18B, the aperture (1818) of the VCSEL (1840) is p-doped and confined in the lateral plane by an oxide (1819). The layer (1809) between the p-doped aperture (1818) and undoped active region (903) is initially undoped. A high doping level in the aperture (1808) results in an induced doping in the part (1808) of the initially undoped layer. At the same time, the part of the layer (1809) outside (1808) remains undoped. The area of the p-n junction is now determined by the area of the induced doped (1808) part of the layer (1809). This area is significantly reduced with respect to the area of the mesa (1822). Thus, the device capacitance is reduced accordingly.

FIG. 18D shows schematically a cross-section in the vertical plane of the VCSEL (1860), according to a further embodiment of the present invention. The substrate of the semiconductor structure is etched off, and on the bottom side of the residual semiconductor structure (1855) the bottom dielectric DBR (1865) is mounted. The bottom dielectric DBR (1865) is composed of a sequence of layers with alternating high (1866) and low (1867) refractive index. On the top surface of the semiconductor structure (1855) the top dielectric DBR (1875) is mounted. The top dielectric DBR (1875) is composed of a sequence of layers with alternating high (1876) and low (1877) refractive index. The top contact (1872) is mounted on top of the p-doped layer (1814), and the layer (1814) serves for current spreading.

The VCSEL chip (1860) contains the first mesa (1883) formed of a top dielectric DBR (1875). The second mesa (1882) is etched down to the n-doped current spreading level (1842) of the semiconductor structure (1855). The third mesa (1883) is formed of the n-doped current spreading layer (1842) and bottom dielectric DBR (1865). Initially, the surface area of the p-n junction was determined by the surface area of the mesa (1882).

Similarly, to the embodiments of FIG. 18A through FIG. 18C, the aperture (1818) of the VCSEL (1860) is p-doped and confined in the lateral plane by an oxide (1819). The layer (1809) between the p-doped aperture (1818) and undoped active region (903) is initially undoped. A high doping level in the aperture (1808) results in an induced doping in the part (1808) of the initially undoped layer. At the same time, the part of the layer (1809) outside (1808) remains undoped. The area of the p-n junction is now determined by the area of the induced doped (1808) part of the layer (1809). This area is significantly reduced with respect to the area of the mesa (1822). Thus, the device capacitance is reduced accordingly.

Once a light-emitting device is a miniarray of VCSELs of FIGS. 15A through 15D, 20B, 20D, 21B, and 21C capable for self-injection locking, on the one hand, combining structural features of FIGS. 9C through 10B and of FIGS. 16A through 18D aimed to ultimately reduce the device capacitance, such a device will be capable for a strongly extended amplitude modulation frequency response showing a (−3 dB) cutoff frequency of 50 GHz and higher. By further improvement of the design of a VCSEL miniarray, the extension of the (−3 dB) cutoff frequency, i.e. the extension of the modulation bandwidth up to 100 GHz and beyond, will be feasible.

The typical value of VCSEL capacitance for standard anti-waveguiding λ/2 VCSEL design, e.g., extracted in Ledentsov '25 from the experiment is ˜60 fF to 90 fF for 15-18 μm mesas. We note here that the concept of an antiwaveguiding cavity was disclosed in the U.S. Pat. No. 7,339,965 “OPTOELECTRONIC DEVICE BASED ON AN ANTIWAVEGUIDING CAVITY”, filed Apr. 5, 2005, issued Mar. 4, 2008, invented by the inventors of the present invention, whereas the patent is hereby incorporated herein in its entirety by reference. Once this concept is combined with the concept disclosed in the present invention aimed to significantly reduce the capacitance of the device, like in the embodiments of FIGS. 18A through 18D, the capacitance will be reduced proportionally to the reduction of the area of the p-n junction.

A one skilled in the art will recognize that fabrication of long wavelength VCSELs configured for the spectral range 1300 nm or 1550 nm is challenging. The possible approaches include but are not limited to the growth of an InP-based structure on InP substrate, growth of In(Ga)As quantum-dot-based VCSEL on GaAs substrate, growth of InGaAsN- or InGaAsNSb quantum well-based VCSEL on GaAs substrate, growth of InGaAs quantum-well or quantum-dot-based VCSEL on metamorphic InGaAs buffer layers on GaAs substrate, growth of a wafer-fused VCSEL.

The principles of fabrication and operation of wafer-fused VCSELs are described, i. e., in a non-patent publication by Blokhin, et al. “High power single mode 1300-nm superlattice based VCSEL: Impact of the buried tunnel junction diameter on performance”, IEEE Journal of Quantum Electronics, volume 58, issue 2, pages 1-15, (2022), https://www.doi.org/10.1109/IOE.2022.3141418, wherein this publication is hereby incorporated herein in its entirety by reference.

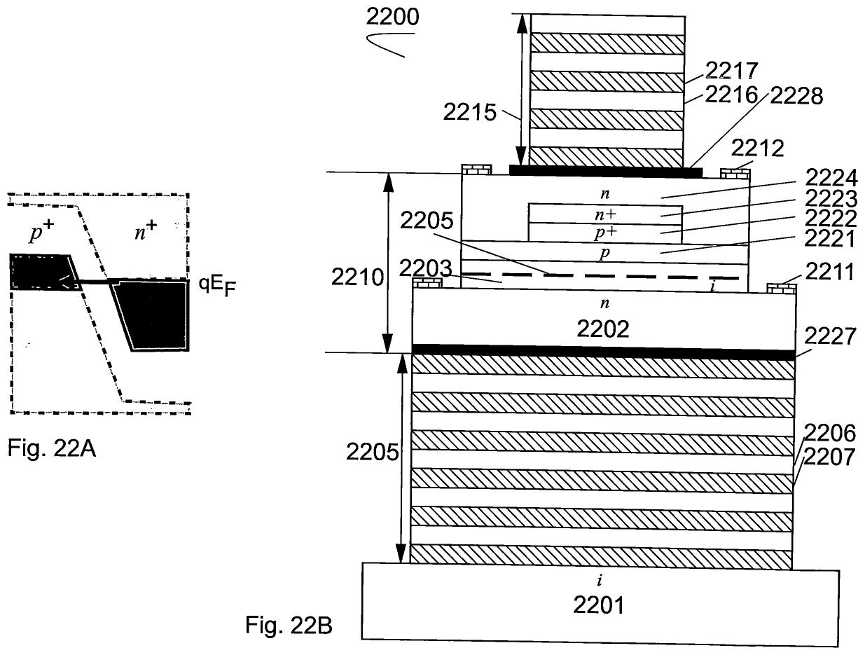

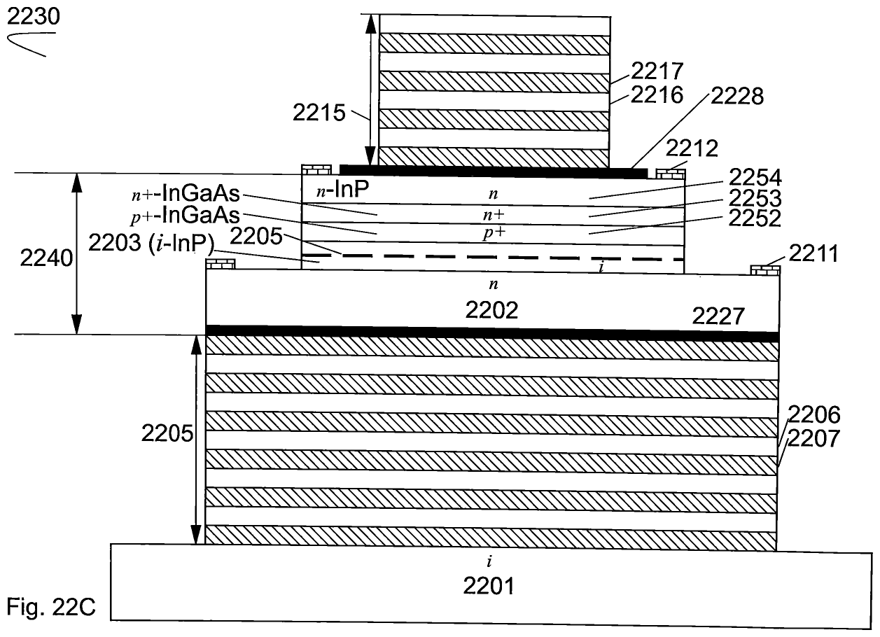

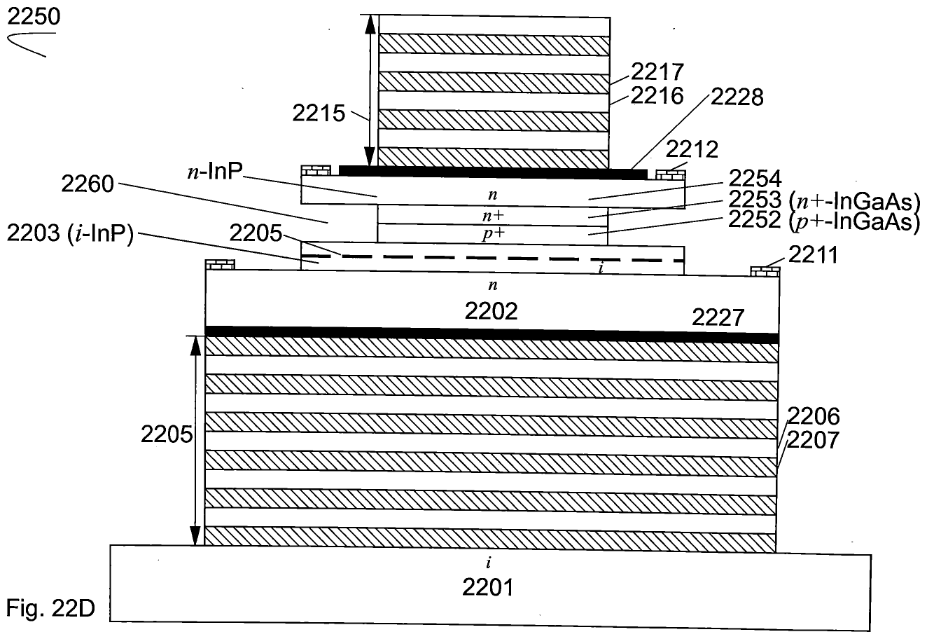

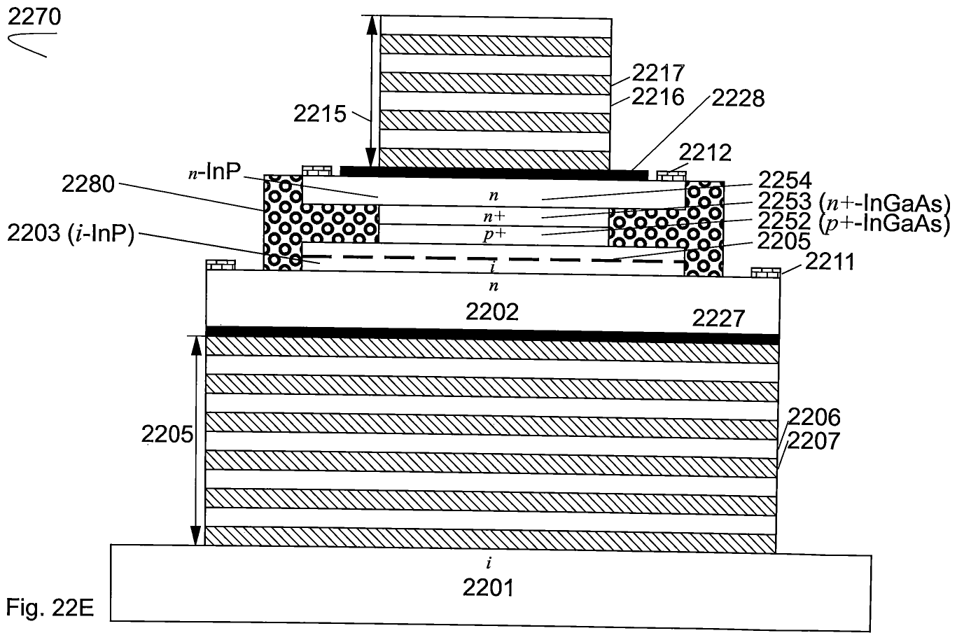

FIG. 22A shows schematically a band diagram of p+/n+ homojunction illustrating the functional principle of the tunnel junction. Tunnel junction is based on basic properties of heavily doped p+ and n+ materials. At high n+ doping levels the Fermi energy is shifted towards conduction band of the n-doped materials. This shift can be significant for narrow gap materials (such as InGaAs lattice-matched to InP) and reaches ˜100 meV at the doping level ˜10¹⁹ cm⁻³. The shift of the Fermi energy into the valence band for heavily p-doped layers is less pronounced due to a larger effective mass and a larger density of states of heavy holes.

FIG. 22B illustrates schematically a cross-section in the vertical plane of a prior art wafer-fusion tunnel-junction-based VCSEL (2200). The structure is composed of three parts. The bottom part is a bottom GaAs/GaAlAs-based DBR (2205) grown on a GaAs-substrate (2201). The bottom DBR (2205) is composed of an alternating sequence of high-index (2206) and low-index (2207) layers. The bottom DBR (2205) is preferably undoped.

The top DBR (2215) is a GaAs/GaAlAs-based DBR grown on a GaAs substrate, wherein the substrate is removed upon growth. The top DBR (2215) is composed of an alternating sequence of high-index (2216) and low-index (2217) layers. The top DBR (2215) is preferably undoped.

The central part (2210) of the VCSEL (2200) is an InP-based active part. The structure is grown on an InP substrate, and the substrate is removed upon growth. The active part (2210) is composed of an n-doped n-current spreading layer (2202), an undoped cavity (2203) with an active medium (2205), a p-doped layer (2221), a p+-doped layer (2222), an n+-doped layer (2223), overgrown by an n-material (2224).

The InP-based epitaxial structure, once grown up to the n+-doped layer (2223) is processed such that the two top layers, the p+-doped layer (2222) and the n+-doped layer (2223) are selectively etched and then overgrown by n-material (2224).

The bottom contact (2211) is mounted on top of the n-current spreading layer (2202), and the top contact (2212) is mounted on top of the n-doped layer (2224).

The InP-based active structure (2210) is fused on top of the bottom DBR (2205) via a bottom fusion interface (2227). The top DBR (2215) is fused on top of the InP-based active structure (2210) via the top fusion interface (2228).

The VCSEL (2200) contains two p-n junctions. The first p-n junction is formed by the n-doped layer (2202), the undoped cavity (2203) with the active medium (2205), and the p-doped layer (2221). The first p-n junction operates, as usually, in semiconductor lasers, under a forward bias. The second p-n junction is formed at the interface between the p+-doped layer (2222) and n+-doped layer (2223). This p-n junction operates under a reverse bias. The current flow occurs due to the tunnel effect and is possible only at the interface between the p+-doped layer (2222) and n+-doped layer (2223). The surrounding area contains a p-n junction between the p-doped layer (2221) and the n-doped layer (2224). However, as the junction is under reverse bias, and no tunnel effect occurs there, there is no current flow via the interface between the layers (2221) and (2224).

Thus, the tunnel junction determines the aperture through which the current flow occurs, and no current flow occurs in the surrounding regions.

However, the p-n junction between the p-doped layer (2221) and the n-doped layer (2224) has a large area, and the device has a large depletion capacitance. Thus, there exists a need to reduce the device capacitance.

FIGS. 22C through 22E describes a wafer-fused tunnel junction-based VCSEL, according to an embodiment of the present invention.

FIG. 22C shows the wafer-fused structure (2230). The active part of the structure (2240) contains the n-doped bottom current spreading layer (2202), the undoped InP-active region (2203), the InGaAs p+-doped layer (2252), the InGaAs n+-doped layer (2253), and the n-doped top current spreading layer (2254).

FIG. 22D shows schematically the next stage of the fabrication process (2250), wherein InGaP-layers (p+-doped (2252) and n+-doped (2253)) are selectively etched from the mesa edge forming a void (2260).

FIG. 22E shows schematically the final stage of the fabrication process and the final structure (2270), wherein the void is filled by a dielectric (2280). The dielectric thus confines the tunnel junction aperture. As the surface of the p-n junction is significantly reduced as compared to a prior art wafer-fused tunnel junction-based VCSEL (2200) of FIG. 22B, the device capacitance is also significantly reduced.

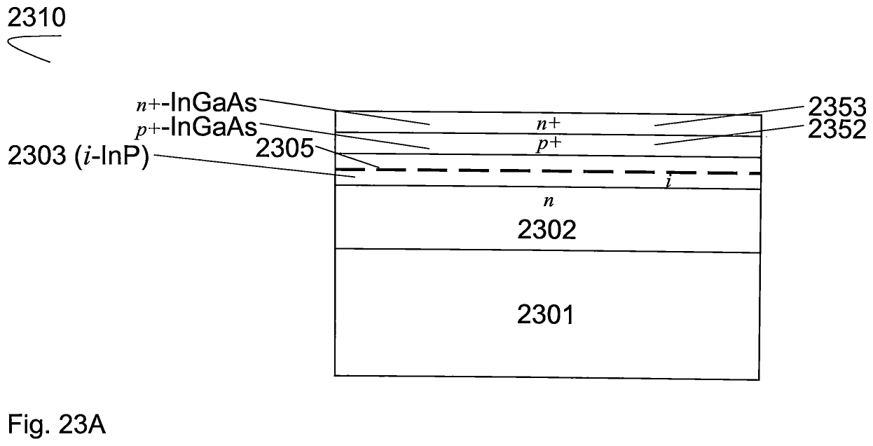

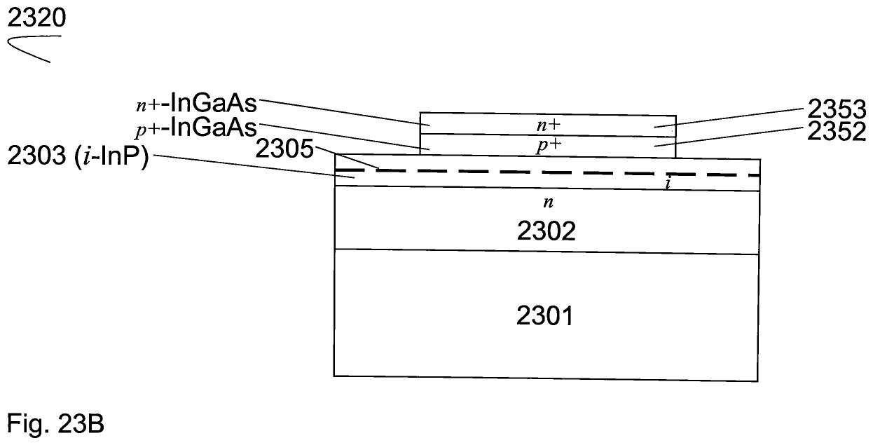

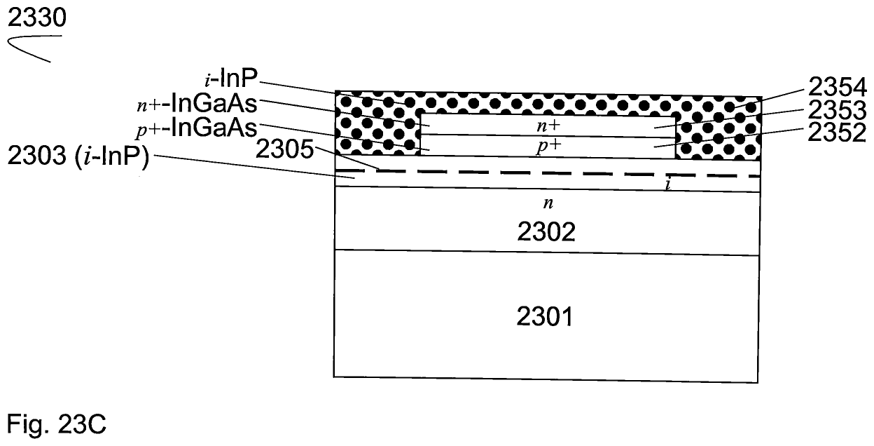

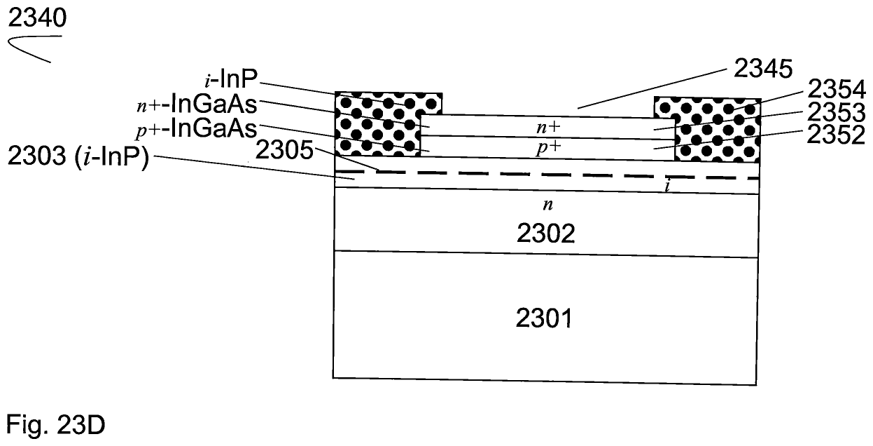

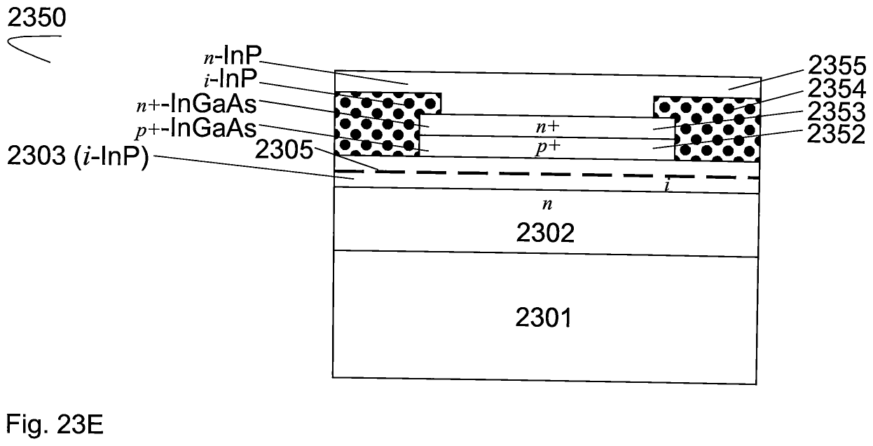

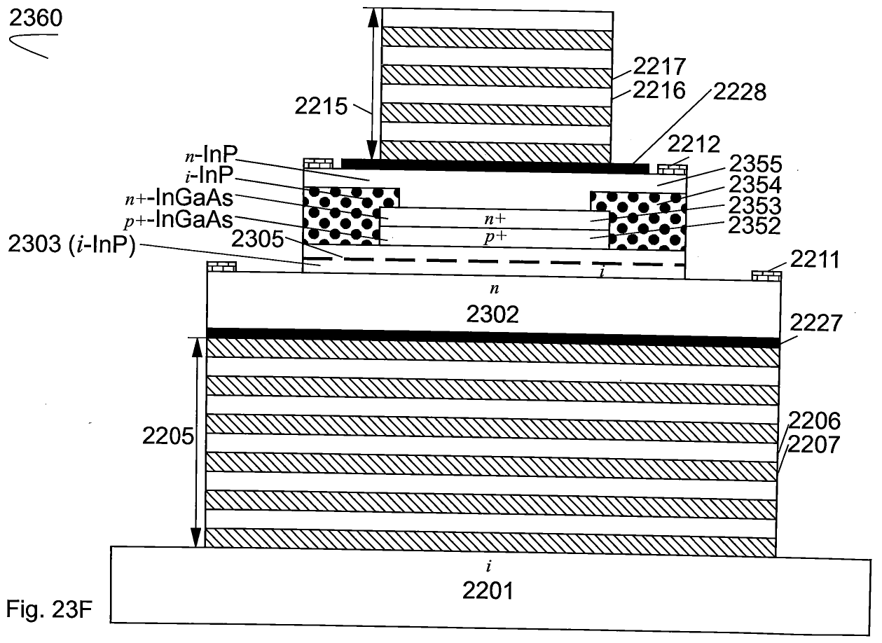

FIGS. 23A through 23F illustrate schematically the key process steps of the fabrication of a wafer-fused tunnel junction-based VCSEL, according to another embodiment of the present invention.

FIG. 23A illustrates an epitaxial structure (2310) grown on an InP-substrate (2301) and containing an n-doped InP bottom current spreading layer (2302), an undoped InP-based active region (2303) with an active medium (2305), a p+-doped GaInAs layer (2352) and an n+-doped InGaAs layer (2353).

FIG. 23B illustrates schematically the next stage (2320) of the process, wherein the two InGaAs layers (the p+-doped layer (2352) and the n+-doped layer (2353)) are selectively partially etched off.

FIG. 23C illustrates schematically the next stage (2330) of the process, wherein the partially etched two InGaAs layers (the p+-doped layer (2352) and the n+-doped layer (2353)) are overgrown by an undoped InP layer (2354).

FIG. 23D illustrates schematically the next stage (2340) of the process, wherein the undoped InP layer (2354) is selectively etched off forming an opening (2345) on top of the n+-doped layer (2353).

FIG. 23E illustrates schematically the next stage (2350) of the process, wherein the n-doped layer (2355) is deposited on top, forming an electrical contact to the n+-doped layer (2353) via the opening in the undoped material.

FIG. 23F illustrates schematically the cross-section in the vertical plane of the final VCSEL structure (2360). The tunnel junction forms an aperture confined in the lateral plane by the undoped material (2354) thus significantly reducing the area of the p-n junction. The device capacitance is reduced accordingly.

A different type of device or a miniarray of devices can be applied. In a further embodiment of the present invention, a device is a surface-emitting tilted cavity laser. Tilted cavity laser (TCL) was disclosed in the U.S. Pat. No. 7,031,360, entitled “TILTED CAVITY SEMICONDUCTOR LASER (TCSL) AND METHOD OF MAKING SAME”, filed Feb. 12, 2002, issued Apr. 18, 2006, and in the U.S. patent application Ser. No. 11/194,181, entitled “TILTED CAVITY SEMICONDUCTOR DEVICE AND METHOD OF MAKING SAME”, filed Aug. 1, 2005, published online Dec. 15, 2005, publication US2005/0276296, both invented by the inventors of the present invention, whereas both are hereby incorporated herein in their entirety by reference. The concept of a tilted cavity laser can be combined with the concept of an undoped region between the doped aperture and the undoped active region resulting in a significant reduction of the device capacitance.

In another embodiment of the present invention, the device is a surface-emitting tilted wave laser. Tilter wave laser (TWL) was disclosed in the U.S. Pat. No. 7,421,001, entitled “EXTERNAL CAVITY OPTOELECTRONIC DEVICE”, filed Jun. 16, 2006, issued Sep. 2, 2008, and in the U.S. Pat. No. 7,583,712, entitled “OPTOELECTRONIC DEVICE AND METHOD OF MAKING SAME”, filed Jan. 3, 2007, issued Sep. 1, 2009, both invented by the inventors of the present invention, whereas both are hereby incorporated herein in their entirety by reference. By employing the concept disclosed in the present invention, of an undoped layer positioned between the doped aperture and the undoped active region, the capacitance of a surface-emitting tilted wave laser can be significantly reduced.

In yet another embodiment of the present invention, a device is a surface-emitting passive cavity laser. Passive cavity laser was disclosed in the U.S. Pat. No. 8,472,496, entitled “OPTOELECTRONIC DEVICE AND METHOD OF MAKING SAME”, filed Jul. 6, 2010, issued Jun. 25, 2013, by one inventor (Ledentsov) of the two inventors of the present invention, whereas the patent is hereby incorporated herein in its entirety by reference. By using an approach disclosed in the present invention, the region between the doped aperture layer and the undoped active region can be undoped, which results in a significant reduction of the capacitance of the surface-emitting passive cavity laser.

In a further embodiment of the present invention, a device can be a quantum cascade laser. The basics of the quantum cascade lasers is described, e.g., in a non-patent publication by Faist et al., “Quantum Cascade Laser”, Science, volume 264, issue 5158, pp. 553-556, Apr. 22, 1994, https://www.doi.org/10.1126/science.264.5158.553, wherein the publication is hereby incorporated herein in its entirety by reference.

In another embodiment of the present invention a device is an edge-emitting laser containing an aperture region and an undoped region between the active region and the aperture, wherein only a part of the undoped region is induced doped enabling electric conductivity. As the effective surface area of the p-n junction is reduced, the capacitance of the device is reduced accordingly.

In yet another embodiment of the present invention a device is a light-emitting diode. The capacitance of the device can be reduced by using the disclosed approaches.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such a reference is available as prior art to the present invention.

Although the invention has been illustrated and described with respect to exemplary embodiments thereof, it should be understood by those skilled in the art that the foregoing and various other changes, omissions and additions may be made therein and thereto, without departing from the spirit and scope of the present invention. Therefore, the present invention should not be understood as limited to the specific embodiments set out above but to include all possible embodiments which can be embodied within a scope encompassed and equivalents thereof with respect to the feature set out in the appended claims.

What is claimed is:

1. A semiconductor optoelectronic device,
wherein said device comprises
a) p-doped region,
b) an undoped active region, and
c) an n-doped region,
wherein said device comprises at least one conducting transformation layer subject to a transformation process,
wherein said at least one conducting transformation layer is doped with a dopant impurity,
wherein said at least one conducting transformation layer is positioned at a position selected from the group consisting of:
i) a position contiguous to said undoped active region, and
ii) a position,
wherein an intermediate region is sandwiched between said conducting transformation layer and said undoped
active region, and
wherein said intermediate region is undoped,
wherein said transformation process of said at least one conducting transformation layer results in a conducting aperture region laterally confined by an electrically insulating region.

2. The semiconductor optoelectronic device of claim 1,
wherein said device is selected from a group consisting of:
a) PIN photodetector,
b) avalanche photodetector,
c) vertical cavity surface-emitting laser,
d) light-emitting diode,
e) edge-emitting laser,
f) tilted cavity laser,
g) tilted wave laser,
h) passive cavity laser,
i) cascade laser, and
j) array of devices of a) through i) formed on a single chip.

3. The semiconductor optoelectronic device of claim 2,
wherein said electrically insulating region is selected from the group consisting of
a) void,
b) dielectric, and
c) any combination of a) and b).

4. The semiconductor optoelectronic device of claim 3,
wherein said transformation process is selected from the group consisting of
a) selective etching of said at least one conducting transformation layer,
wherein said insulating region confining said conducting aperture region is a void,
b) selective oxidation of said at least one conducting transformation layer,
wherein said insulating region confining said conducting aperture region is an oxide layer,
c) selective etching of said oxide layer of b) resulting in a void,
d) filling said void of a) or c) by dielectric, and
e) any combination of a) through d).

5. The semiconductor optoelectronic device of claim 4,
wherein said p-region and said n-region form a p-n junction,
wherein said transformation process results in a reduction of the surface area of said p-n junction.

6. The semiconductor optoelectronic device of claim 2,
wherein said undoped active region is unintentionally doped to a residual doping level below 5E16 (five times ten to the sixteenth power) reciprocal cubic centimeters and is thus effectively undoped.

7. The semiconductor optoelectronic device of claim 2,
wherein said device contains an interface between said electrically insulating region of said conducting transformation layer, on the one hand, and said intermediate region, on the other hand,
wherein said interface contains a surface concentration of deep centers, capable of localizing mobile carriers,
wherein said intermediate region is selected from the group consisting of
i) unintentionally doped intermediate region with a residual doping below 5E16 (five times ten to the sixteenth power) reciprocal cubic centimeters, and
ii) intentionally weakly doped intermediate region to a low doping level below 5E17 (five times ten to the seventeenth power) reciprocal cubic centimeters,
wherein said low doping level multiplied by a thickness of said intermediate region is less than said surface concentration of deep centers, such that the mobile carriers are localized by said deep centers, and said intermediate region is effectively undoped.

8. The semiconductor optoelectronic device of claim 2,
wherein said conducting transformation layer is suitable for induced doping of a part of said intermediate region sandwiched between said undoped active region and said aperture region of said conducting transformation layer,
wherein said induced doping is driven by band alignment at the heterointerface between said intermediate region and said aperture region of said conducting transformation layer,
wherein said induced doping of said part of said intermediate region renders said part of said intermediate region locally electrically conducting, and
wherein said locally electrically conducting part of said intermediate region is laterally confined by an undoped and electrically insulating part of said intermediate region.

9. The semiconductor optoelectronic device of claim 4,
wherein the process of fabrication of said device includes processing of several local holes in the chip to expose at least one conducting transformation layer to enable formation of the electrically insulating regions.

10. The semiconductor optoelectronic device of claim 9,
wherein other regions of said device distinct from said electrically insulating regions remain mechanically connected through the unetched sections of the device and maintain the coherent defect free crystalline semiconductor structure.

11. The semiconductor optoelectronic device of claim 2,
wherein said device contains at least two transformation layers,
wherein said at least two transformation layers contain a first transformation layer and a second transformation layer distinct from said first transformation layer,
wherein said first transformation layer forms, upon said transformation process, a first aperture region laterally confined by said electrically insulating region of said first transformation layer,
wherein said second transformation layer forms, upon said transformation process, a second aperture region laterally confined by said electrically insulating region of said second transformation layer,
wherein said first aperture region and said second aperture region are vertically stacked,
wherein said first aperture region and said second aperture region are doped,
wherein at least one separating layer is positioned between said first transformation layer and said second transformation layer,
wherein said at least one separating layer is an undoped layer selected from the group consisting of:
a) unintentionally doped separating layer to a residual doping level below 5E16 (five times ten to the sixteenth power) reciprocal cubic centimeters, and
b) intentionally weakly doped separating layer to a low doping level below 5E17 (five times ten to the seventeenth power) reciprocal cubic centimeters,
wherein said low doping level multiplied by a thickness of said separating layer is less than a sum of surface concentration of deep centers at an interface between said separating layer and said electrically insulating region of said first transformation layer, on the one hand, and of surface concentration of deep centers at an interface between said separating layer and said electrically insulating region of said second transformation layer, on the other hand, such that the mobile carriers are localized by said deep centers, and said separating layer is effectively undoped,
wherein said first aperture region and said second aperture region are capable for induced doping of a part of said at least one separating layer.

12. The semiconductor optoelectronic device of claim 2,
wherein said semiconductor optoelectronic device represents an in-plane array of apertures of sizes, shapes and relative distances allowing on-chip arrays with relative spacings between the centers of the apertures below 100 (one hundred) micrometers.

13. The semiconductor optoelectronic device of claim 12,
wherein said semiconductor optoelectronic device represents an in-plane array of apertures of sizes, shapes and relative distances allowing on-chip arrays with relative spacings between the centers of the apertures below 10 (ten) micrometers.

14. The semiconductor optoelectronic device of claim 2, further comprising an in-plane array of apertures,
wherein at least one first aperture is fully electrically isolated from at least one second aperture,
wherein a contact to said first aperture and a contact to said second aperture are electrically different contacts,
wherein the current and the voltage can be applied to said first aperture and to said second aperture independently.

15. The semiconductor optoelectronic device of claim 11,
wherein the configuration of said vertically stacked aperture regions is selected from two geometries:
a) all the stacked apertures have identical shape and size,
b) stacked apertures have different sizes and/or shapes,
wherein said different sizes and shapes are realized by an approach selected from the group of approaches:
i) different thicknesses of the aperture regions,
ii) different chemical compositions of the aperture regions, and
iii) any combination of (i) and (ii).

16. The semiconductor optoelectronic device of claim 2,
wherein said semiconductor optoelectronic device is an injection laser,
wherein said injection laser comprises at least two laterally optically coupled apertures,
wherein said apertures demonstrate, upon injection of non-equilibrium carriers, an effect selected from the group of effects consisting of:
a) self-injection mode locking resulting is single mode lasing from said at least two optically coupled apertures, and
b) oscillations in each of said at least two optically coupled apertures,
wherein the frequency of said oscillations is defined by the difference in photon energies of the optical modes attached to said at least two laterally optically coupled apertures.

17. The semiconductor optoelectronic device of claim 16,
wherein at least one of said at least two laterally optically coupled apertures is subjected to a process selected from the following group of processes consisting of:
(i) said aperture is masked by a metal layer,
(ii) said aperture is capped by a highly reflective coating,
(iii) said aperture is capped by an anti-reflective coating, and
(iv) said aperture is capped by a diffraction grating, and
(v) said aperture is locally etched,
such that at least one of coupled optical modes is suppressed stimulating self-injection locking.

18. The semiconductor optoelectronic device of claim 16, further comprising at least one bridge connecting said at least one first aperture and at least one second aperture,
wherein said at least one bridge is subjected to a process selected from the following group of processes consisting of
(i) said bridge is capped by an anti-reflective coating, and
(ii) said bridge is partially etched,
such that at least one of coupled optical modes is suppressed stimulating self-injection locking.

19. The semiconductor optoelectronic device of claim 16,
wherein said self-injection locking results in single mode lasing of said semiconductor optoelectronic device.

20. The semiconductor optoelectronic device of claim 16,
wherein said self-injection locking results in a modulation response of said semiconductor optoelectronic device having (−3 dB) cut-off frequency above 50 GHz (fifty gigahertz).

21. The semiconductor optoelectronic device of claim 16,
wherein said semiconductor optoelectronic device is used for an application selected from the group consisting of:
a) high speed digital data transmission,
b) generation of a high frequency optical signal,
c) generation of a high frequency electrical signal,
d) beam steering, and
e) any combination of a) through d),
wherein the operation of said device is determined by interaction of optical fields in optically coupled apertures,
wherein said interaction occurs via the electron-hole plasma in the active medium,
wherein said interaction results in an effect selected from the group consisting of:
(i) self-injection locking and
(ii) mode beating resulting in generation of a high frequency signal.

22. The semiconductor optoelectronic device of claim 2,
wherein said at least one conducting transformation layer is fully removed such that
the resulting structure comprises at least one distributed Bragg reflector (DBR),
wherein the number and positioning of said at least one DBR is selected from the group of possible arrangements consisting of:
a) at least one DBR is a first DBR positioned above the active region,
b) at least one DBR is a second DBR positioned below the active region,
c) at least one DBR is at least two DBRs comprising a first DBR and a second DBR,
wherein said first DBR is positioned above the active region, and
wherein said second DBD is positioned below the active region.

23. The semiconductor optoelectronic device of claim 11,
wherein said vertically stacked aperture regions form electrically isolated columns,
wherein said electrically isolated columns enable formation of an under-pad electric circuit,
wherein said under-pad electric circuit minimizes back reflection of a high frequency signal.

24. The semiconductor optoelectronic device of claim 2,
wherein said conducting aperture has lateral dimensions below 15 (fifteen) micrometers.

25. The semiconductor optoelectronic device of claim 24,
wherein said conducting aperture has lateral dimensions below 10 (ten) micrometers.

26. The semiconductor optoelectronic device of claim 5,
wherein said reduction of the surface area of said p-n junction is a reduction by at least thirty percent.

27. The semiconductor optoelectronic device of claim 26,
wherein said reduction of the surface area of said p-n junction is a reduction by at least fifty percent.

28. The semiconductor optoelectronic device of claim 2,
wherein said undoped active region is selected from the group consisting of:
a) undoped gain region in a light emitting device, and
b) undoped absorption region in a photodetector.
